(19) United States
(12) Patent Application Publication
(10) Pub. No.: US 2025/0212706 A1
(43) Pub. Date: Jun. 26, 2025

(54) PHASE CHANGE MEMORY DEVICE WITH IMPROVED TEMPERATURE STABILITY

(71) Applicant: COMMISSARIAT A L'ENERGIE ATOMIQUE ET AUX ENERGIES ALTERNATIVES, Paris (FR)

(72) Inventors: Jean-Baptiste DORY, Grenoble Cedex 09 (FR); Guillaume BOURGEOIS, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/989,365

(22) Filed: Dec. 20, 2024

(30) Foreign Application Priority Data
Dec. 21, 2023 (FR) FR2314750

(51) Int. Cl. H10N 70/00; H10B 63/10; H10N 70/20

(52) U.S. Cl. CPC H10N 70/8413; H10B 63/10; H10N 70/011; H10N 70/231

(57) ABSTRACT

A phase change memory device including a memory point, the latter including a metal layer forming a heating element, a memory layer with the basis of a phase change material and an upper electrode. The device moreover includes a first encapsulation layer extending from a first main flank of the metal layer and having a doped portion with the basis of at least one first doping species. The doped portion extends from the first main flank of the metal layer.

### TECHNICAL FIELD

The present invention relates to the field of phase change memory devices. It has a particularly advantageous application in memory devices, the architecture of the memory points of which includes a heating element underlying the memory layer.

### PRIOR ART

Memory devices represent crucial challenges in numerous applications, for example, for the type of memory commonly called Storage Class Memory (SCM), embedded memories for motor vehicles, or neuromorphic applications. In this context, resistive memories represent very good candidates to support or replace Flash memory. Resistive memories indeed have significant advantages in terms of speed and of scaling, i.e. reducing dimensions of the memory unit cell, and of the distance between two memory points, which has the effect of increasing the density of memory points in the memory matrices. From among resistive memories, phase change memories (PCM) represent non-volatile resistive memory technology from among the most mature, and at an advanced development and production stage. Phase change memories typically comprise two programming states obtained from a layer with the basis of a phase change material forming a so-called “memory” layer, and having an amorphous state and a crystalline state:
a. “RESET” or equivalently, HRS (High Resistive State) programming, which is based on the melting of all or some of the chalcogenide layer, during an electric pulse making it possible to reach the melting point of the material by Joule effect. The molten part of the chalcogenide material is then frozen in an amorphous state by sudden cooling, obtained by rapid reduction of the current. The amorphous state of the chalcogenide material is very slightly electrically conductive. The reset programming makes it possible to store the information “0”, with a high resistance in the PCM device.
b. “SET” or equivalently LRS (Low Resistive State) programming, which is based on a partial or total melting of the chalcogenide material during an electric pulse. The chalcogenide material is then crystallised by a gradual cooling obtained by gradual reduction of the current. The crystalline state of the chalcogenide material is a better electrical conductor than the amorphous state. The set programming makes it possible to store the information “1”, with the storage of a low resistance in the PCM device.

The optimisation work of memories of this type is today based, among other things, on decreasing the deviation of the “SET” state and on reducing the size of the memory point. However, the vertical extension of the PCM unit cell is a significant parameter given its impact on the passive resistance of the vertical metal connections in the metal vias of the integrated devices at the same level. In the integration of the most common PCM cells, a significant part of the vertical dimension of the PCM cell corresponds to the heating element (commonly called “heater”) located under the phase change material. This heating element is at the core of the operation of the PCM cell: when it is crossed by a current, it emits, by Joule effect, heat propagating in the memory layer and modifying the state of the phase change material. According to the quantity of heat emitted by the heating element, the memory layer passes from the “SET” state to the “RESET” state, or conversely.

The performance of the heating resistive element are first very sensitive to its dimensions. In particular, a quite fine heating element is preferred (a few nanometres or tens of nanometres thick), in order to maximise the Joule effect occurring within it. In this way, controlling the state of the memory layer, and therefore the performance of the device is improved.

The performance of the heating resistive element are moreover very sensitive to the properties of the material which composes it. Yet, the deposition methods making it possible to produce the heating element at the preferable dimensions mentioned above (chemical vapour deposition, alternate flow chemical deposition) impose limits in terms of composition of the heating element. This is due to different parameters, in particular the precursors used, the reactivity of the elements in play or also the temperature at which these deposition methods can be carried out. Thus, the range of materials which can be considered for the heating element is restricted, and the latter do not have the most advantageous physical properties for the operation of the memory point. In particular, the materials being able to be deposited by the methods mentioned above do not have an optical stability at the operating temperatures of the memory point. Thus, there is a need to improve thermal properties of the memory point, while preserving a heating element having dimensions favouring the performance of the device.

### SUMMARY

To achieve this aim, a first aspect of the invention relates to a phase change memory device comprising a memory point, the memory point comprising:
a. a metal layer with the basis of a metal material and forming a heating element,
b. a memory layer with the basis of a phase change material, the phase change material being configured such that the memory layer passes selectively from a first resistive state (LRS) having a first resistivity to a second resistive state (HRS) having a second resistivity greater than the first resistivity,
c. an upper electrode.

The heating element is intended to receive an electric current making it possible to produce heat by Joule effect and to transfer some of this heat to the memory layer so as to make the memory layer pass selectively from one from among the first resistive state (LRS) and the second resistive state (HRS) to the other from among the first resistive state (LRS) and the second resistive state (HRS). According to an embodiment, the heating element can also make the memory layer pass selectively from the first resistive state (LRS) or from the second resistive state (HRS) to a third resistive state having a third resistivity, different from the first resistivity and from the third resistivity, and conversely. Generally, the heating element can be configured to be able to make the memory layer place selectively in N levels, with N an integer greater than or equal to 2, each level being characterised by a different resistivity. When N is strictly greater than 2, the memory device is qualified as multilevel and makes it possible to code more information at one same memory point. This can, for example, make it possible to manufacture artificial neural networks.

The heating element has a first main flank and a second main flank, opposite one another.

The memory device further comprises a first encapsulation layer extending from the first main flank of the metal layer. The first encapsulation layer has a portion, called doped, having a doping with the basis of at least one species, called first doping species, the doped portion extending from the first main flank of the metal layer. Preferably, the metal layer has a doping with the basis of a second doping element, preferably identical to the first doping species.

The doping of the first encapsulation layer makes it possible to improve the thermal resistivity of the memory point. In particular, this doping makes it possible to reduce the value of the thermal transfer coefficient of the first encapsulation layer, which enables a certain thermal confinement of the heating element, less dissipation of heat from the heating element to the regions of the device, other than the memory layer, and therefore a reduction of the energy necessary for the programming of the “RESET” state. The doping of the first encapsulation layer thus makes it possible to use materials authorising the formation of a memory layer at advantageous dimensions such as mentioned above, while guaranteeing a very good ratio between the energy used to heat the heating element, and the energy actually transmitted to the memory layer. The invention therefore makes it possible to reach the aim outlined above, namely to improve the thermal properties of the memory point, which leads to an improvement of its performance. The thermal confinement effect of the heating element is moreover further improved when the device comprises a second encapsulation layer, itself also doped.

The presence of the first encapsulation layer moreover makes it possible to limit the degradations of the metal layer due to a potential venting. With this in mind, it is advantageously provided that the first encapsulation layer is deposited consistently on the metal layer.

Preferably, the metal layer is also doped, for example, with the same doping species as the first encapsulation layer. The doping of the metal layer makes it possible to modify its stoichiometry and the atomic structure, as well as adding new chemical elements within it. Moreover, the doping of the metal layer makes it possible to obtain a very good temperature stability of the heating element, which makes it possible to improve the performance of the memory device.

Moreover, by improving the temperature stability through doping, the number of material being able to be used to form the heating element increases. Materials which previously were not good candidates to produce the heating element due to their poor temperature stability, but which had other advantageous physical properties, can be used. Indeed, the implantation makes it possible to make up for the natural temperature stability, and thus to give the heating element a satisfactory, even greater temperature stability, to which would have been obtained by using materials naturally having a correct temperature stability but not having been doped.

Moreover, the doping of the metal layer makes it possible to give the latter a better resistivity, which is very advantageous to enable a strong Joule effect at the heating element and therefore a better control of the state of the memory layer.

A second aspect of the invention relates to a method for manufacturing a phase change memory device comprising a memory point, the method comprising the following steps:
a. providing an assembly comprising at least:
   i. a metal layer with the basis of a metal material and intended to form a heating element for the memory point, the metal layer having a first main flank,
   ii. a first encapsulation layer extending from the first main flank of the metal layer,
b. implanting a species called first doping species in a so-called doped portion, of the first encapsulation layer, the doped portion extending from the main flank of the metal layer,
c. forming against a face of the metal layer, a stack comprising:
   i. a layer called memory layer, with the basis of a phase change material, thermally coupled with the metal layer, such that the heat produced by Joule effect by the metal layer is transferred to the memory layer,
   ii. an upper electrode.

Preferably, the method also comprises a step of doping the metal layer, for example, with the same doping species as the first encapsulation layer. The implantation of the metal layer, and therefore of the heating element, enables not only a modification of its composition, but also its amorphisation. Indeed, the methods generally used to form the metal layer (in particular, alternate flow chemical deposition, which makes it possible to obtain very fine layers) operate by saturating the structure by a face, layer after layer. Thus, planes are obtained along an ordered stack, which constitutes a conduction path which is easy to follow for the current. As it is, the resistivity of the heating element is therefore low. Consequently, the Joule effect is not very significant, which is unfavourable for the operation of the memory point. By performing the implantation of the heating element, this stack is disordered, which makes it possible to increase the resistivity of the heating element, therefore to increase the Joule effect, and finally to improve the control of the programming, and to increase the performance of the memory point.

Preferably, the step of implanting the metal layer is carried out through the first encapsulation layer. Performing the implantation through the first encapsulation layer makes it possible to transfer species from the first encapsulation layer until into the metal layer. This transfer is particularly favourable when the transferred species can contribute to an increase of the resistivity and of the temperature stability of the metal layer, which is in particular the case when the first encapsulation layer comprises silicon and/or nitrogen. The implantation thus enables an increase of the resistivity and an increase of the temperature stability of the metal layer, not only thanks to the implantation of the doping species, but also to the implantation of one or more species coming from the first encapsulation layer.

It must be noted that the implantation of the first encapsulation layer (and optionally of the memory layer) is compatible with all the PCM architectures integrating a heating element underlying the memory layer. Moreover, the extra cost of this step is low, for an increase in performance of the memory device.

The advantages provided by the memory device according to the invention will apply mutatis mutandis to the method according to the invention, and conversely.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 represents a cross-sectional view illustrating, according to an example, the placement of a PCM device between the metal levels at the manufacturing back-end.

FIG. 2 represents a perspective diagram of a memory point according to an example of an embodiment.

FIGS. 3A to 23B illustrate an embodiment of the method according to the invention.

FIG. 24 represents the result of a simulation of the carbon implantation of a SiN/TiN/SiN tri-layer.

FIGS. 25A to 25D are cross-sectional views of embodiments of the device according to the invention in which the memory point has different structures.

The drawings are given as examples and are not limiting of the invention. They constitute principle schematic representations intended to facilitate the understanding of the invention and are not necessarily to the scale of practical applications. In particular, the dimensions and relative dimensions of the layers are not representative of reality.

### DETAILED DESCRIPTION

Before starting a detailed review of embodiments of the invention, optional features are stated below, which can optionally be used in association or alternatively:

According to an example, the first encapsulation layer is with the basis of at least one from among the following materials: SiN, SiCN, SiC.

According to an example, the concentration of first doping species in the doped portion of the first encapsulation layer is greater than or equal to 5·10²⁰ atoms/cm³, preferably greater than or equal to 1.10²¹ atoms/cm³. Typically, the concentration of first doping species in the doped portion of the first encapsulation layer is less than or equal to 1.10²² atoms/cm³.

According to an example, the first encapsulation layer has a thickness e₄₀₀ taken along a direction perpendicular to the first main flank of the metal layer, the doped portion extending over a thickness e₄₅₀ along this same direction within the first encapsulation layer, with e₄₅₀≥0.05*e₄₀₀, preferably e₄₅₀≥0.10*e₄₀₀.

According to an example, the first encapsulation layer has a thickness e₄₀₀ taken along a direction perpendicular to the first main flank of the metal layer, the doped portion extending over a thickness e₄₅₀ along this same direction within the first encapsulation layer, with e₄₅₀≤0.5*e₄₀₀, preferably e₄₅₀≤0.3*e₄₀₀. The rest of the first encapsulation layer (being able to be called non-doped portion) is itself preferably less doped than the doped portion. The so-called non-doped portion is preferably doped, due to a concentration strictly less than 5.10²⁰ atoms/cm³. It is thus guaranteed that a significant portion of the encapsulation layer is less doped than the doped portion. In this way, the doped portion of the encapsulation layer ensures the thermal confinement of the metal layer, while the non-doped portion ensures the protection of the metal layer. The thickness e₄₅₀ of the doped portion in the encapsulation layer can be controlled by means known to a person skilled in the art during the implantation of the encapsulation layer (modulation of the implantation energy, of the implantation angle, etc.).

According to an example, the metal layer has a thickness e₃₀₀ between its first main flank and its second main flank, with e_{300≤10} nm. This makes it possible to maximise the Joule effect occurring in the metal layer and thus improve the control of the state of the memory layer.

According to a preferred embodiment, the metal layer comprises a so-called main portion extending from the flank of the dielectric layer and a portion called protrusion extending transversely from the main portion. The main portion and the protrusion of the metal layer preferably extend mainly in substantially perpendicular directions. Typically, the protrusion of the metal layer extends from an upper face of an underlying metal via. Typically, the metal layer has a substantially invariant shape in a direction perpendicular to the stacking direction. The metal layer typically has an “L” shape when projected in a plane parallel to the stacking direction.

In a preferred example, the first encapsulation layer extends above the protrusion of the metal layer. Preferably, the first encapsulation layer extends only above the protrusion of the metal layer. Thus, in a direction perpendicular to the main flank of the metal layer, the first encapsulation layer does not extend beyond the protrusion of the metal layer. The first encapsulation layer may, for example, extend as far as the protrusion of the metal layer in this same direction. The first encapsulation layer is thus preferably located in the hollow defined by the ‘L’ formed by the metal layer.

According to a typical example, the thickness of the first encapsulation layer varies along the stacking direction. Typically, the thickness of the first encapsulation layer decreases away from the protrusion of the metal layer. As a result, the first encapsulation layer has a base that is wider than its top, its base typically being in contact with the protrusion of the metal layer.According to a preferred embodiment, the metal layer has a doping with the basis of a second doping species, preferably identical to the first doping species. It can also be considered that the metal layer has a doping with the basis of a second doping species distinct from the first doping species, and a doping with the basis of the first doping species. Whether the second doping species is identical or not to the first doping species, the concentration of second doping species within the metal layer is preferably between 0% and 8%.

In a preferred example, the first main side of the metal layer is fully doped. In other words, the first main side of the metal layer is preferably doped over its entire height. Preferably, the first main side of the metal layer is uniformly doped.

According to a preferred embodiment, the device further comprises a first dielectric layer extending from the second main flank of the metal layer, the first dielectric layer having a portion, called doped, having a doping with the basis of at least one species, called third doping species, preferably identical to the first doping species, the doped portion of the first dielectric layer extending from the second main flank of the metal layer. The advantages obtained by doping of the first encapsulation layer are also obtained by doping of the first dielectric layer (thermal confinement of the metal layer, in particular).

According to an example, the concentration of third doping species in the doped portion of the first dielectric layer is greater than or equal to 5.10²⁰ atoms/cm³, preferably greater than or equal to 1.10²¹ atoms/cm³. Typically, the concentration of third doping species in the doped portion of the first dielectric layer is less than or equal to 1.10²² atoms/cm³.

Preferably, the third doping species is identical to the second doping species. It can also be considered that the doped portion of the first dielectric layer has a doping with the basis of a third doping species distinct from the second doping species, and a doping with the basis of the second doping species, even also a doping with the basis of the first doping species.

According to an example, the first encapsulation layer has a first main flank and a second main flank opposite one another, the second main flank facing the first main flank of the metal layer, the device further comprising a second encapsulation layer against the first main flank of the first encapsulation layer. The second encapsulation layer advantageously has a doping, preferably with the basis of the first doping species.

According to an example, the first doping species is chosen from among the following species: silicon, carbon, argon, nitrogen, oxygen, xenon, titanium, tantalum, tungsten, cobalt, germanium, neon and their alloys. The atomic proportions of these alloys are not compulsorily fixed at 1:1. As will be described further, distinct doping species can be implanted during different implementation substeps, both for implanting one or even more layer(s), and for implanting distinct layers. Argon, xenon, nitrogen, oxygen, carbon, silicon and germanium are quite specifically advantageous for decreasing the thermal diffusion coefficient of the first encapsulation layer (and, if necessary, of the second encapsulation layer).

Preferably, the second implanted species is identical to the first implanted species. Generally, the second implanted species can be chosen from among the same doping species as the first implanted species. All these species have the effect, when they are implanted in the metal layer, of improving its temperature stability.

Argon, xenon, nitrogen, oxygen, carbon, silicon and germanium are moreover quite specifically advantageous for increasing the electrical resistivity of the metal layer and thus increasing the Joule effect. Argon and xenon in particular act on the resistivity of the metal layer by modifying its structure. Their implantation in the metal layer causes an amorphisation which causes the increasing of resistivity. Nitrogen, oxygen, carbon, silicon and germanium themselves modify the composition of the material constituting the metal layer, which causes the increasing of resistivity.

Preferably, the third implanted species is identical to the first implanted species. Generally, the third implanted species can be chosen from among the same doping species as the first implanted species.

According to an example, along a direction perpendicular to the first main flank of the metal layer, the memory layer has a length L_{cm} and the heating element has a thickness e_{ec}, with L_{cm}>γe_{ec}, with γ>2, preferably γ>5, preferably γ>10.

According to an example, the metal material is with the basis of at least one from among the following materials: TiN, TiC, TiSiN, TiSiCN, TiWN, TaN, TaCN. The atomic proportions of these alloys are not compulsorily fixed at 1:1.

According to an example, the metal layer has a lower face and the device further comprises a metal via in contact with the lower face of the metal layer.

According to an advantageous embodiment of the method according to the invention, the latter further comprises a step of implanting a species called a second doping species, preferably identical to the first doping species, in the metal layer, the step of implanting the metal layer being performed through the first encapsulation layer.

As will be seen further, the first encapsulation layer can also serve as a protective layer during the etching of a portion of the metal layer. With this in mind, it is advantageously provided that the first encapsulation layer is deposited consistently on the metal layer.

According to an example, the first encapsulation layer has a first main flank and a second main flank opposite one another, the second main flank facing the first main flank of the metal layer, and the method further comprises the formation of a second encapsulation layer against the first main flank of the first encapsulation layer.

According to an example, the second encapsulation layer is with the basis of at least one from among the following materials: SiN, SiCN, SiC.

According to an example, the implantation of the second doping species in the metal layer is performed through the second encapsulation layer. Performing the implantation of the metal layer through the second encapsulation layer has the same advantages as performing it through the first encapsulation layer, this time with two layers from which species can be transferred into the metal layer and increase its resistivity. Thus, it can be provided that the implantation is performed so as to transfer until into the heating element, a doping species coming from the first encapsulation layer and a different doping species, this time coming from the second encapsulation layer. The properties of the heating element can be improved by the implantation of these two distinct species. To favour the transfer of doping species from the second encapsulation layer to the metal layer, it can be provided that the thickness e₄₀₀ of the first encapsulation layer is low, for example, less than or equal to 1 nm.

According to an example, the first main flank of the metal layer is not covered during the step of implanting the second doping species. The step of providing the assembly at the start of the method can thus comprise the following steps:
a. Providing the metal layer,
b. Implanting the metal layer with the second doping species,
c. Forming the first encapsulation layer.

According to an example, providing the assembly comprises the following steps:
a. Providing a support layer having an upper face extending mainly into a plane parallel to the longitudinal plane,
b. Forming a dielectric layer on a portion of the upper face of the support layer, the dielectric layer having a flank preferably extending mainly into a plane parallel to the transverse plane,
c. Forming the metal layer against the flank of the dielectric layer, and preferably on the upper face of the support layer.

Using a support layer to form the metal layer makes it possible to form this with more accuracy. This also makes it possible to give the metal layer the desired shape without resorting to etching steps, which could damage it.

According to an example, the dielectric layer comprises a first dielectric layer and a second dielectric layer, the second dielectric layer and the support layer being separated by the first dielectric layer, and the method further comprises a step of polishing an upper portion of the metal layer and of the second dielectric layer, with a selective stop on the first dielectric layer. The polishing step can, in particular, occur before the step of forming the memory layer, and preferably, after the implantation step.

In order to enable a selective polishing of the second dielectric layer selectively at the first dielectric layer, these two dielectric layers are of different natures. For example, the first dielectric layer can be SiN-based and the second dielectric layer can be SiO₂-based.

Resorting to a support layer comprising two layers of different natures and performing a polishing of the metal layer stopping when the second dielectric layer is fully depleted, makes it possible to control the height of the metal layer very well. Stopping the polishing is done without damaging the portion of the remaining metal layer.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements. Thus, a material with the basis of a III-N material can comprise a III-N material added with dopants.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA: B.

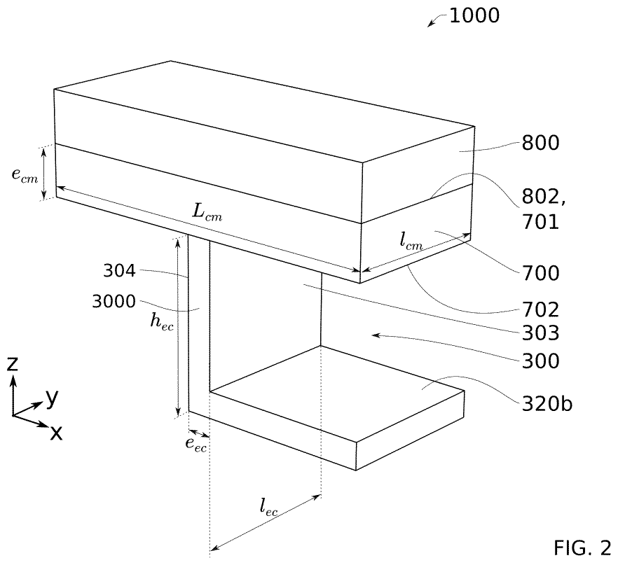

A preferably orthonormal system, comprising the axes X, Y, Z is represented in FIGS. 2 to 23B and 25A to 25D. The direction Z can be called “stacking direction”.

In the present patent application, thickness is preferably referred to for a layer and height is preferably referred to for a structure or a device. The height is taken perpendicularly to the longitudinal plane XY. The thickness is taken along a direction normal to the main extension plane of the layer. Thus, a layer or layer portion typically has a thickness along Z, when it extends mainly along the longitudinal plane XY, and a projecting element, for example, an isolation trench, has a height along Z. The relative terms “on”, “under”, “above”, “below”, “underlying” preferably refer to positions taken along the direction Z.

The terms “substantially”, “about”, “around” mean, unless mentioned otherwise, “plus or minus 10%, preferably plus or minus 5%”.

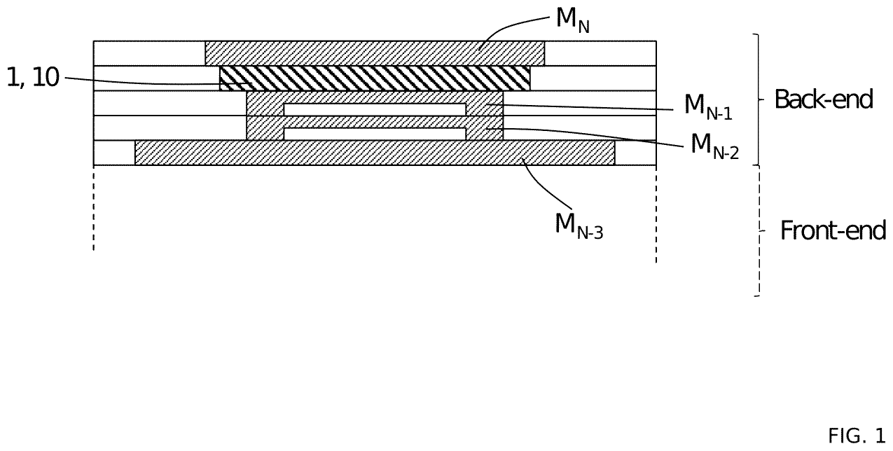

A PCM device 1 is typically manufactured at the back-end. The PCM device 1 and its substrate can be disposed between two metal levels M of the back-end, in particular between the last two levels, for example, between M_{N} and M_{N-1} as illustrated in FIG. 1. The position of the part of the device manufactured at the front-end is indicated by the dotted line in FIG. 1. The integrations can more generally go up to ten metal levels or more. The term “substrate” does not necessarily mean a monolayer and can comprise a stack of layers, in particular, in the scope of a back-end manufacture.

### Method for Manufacturing a Phase Change Memory Device

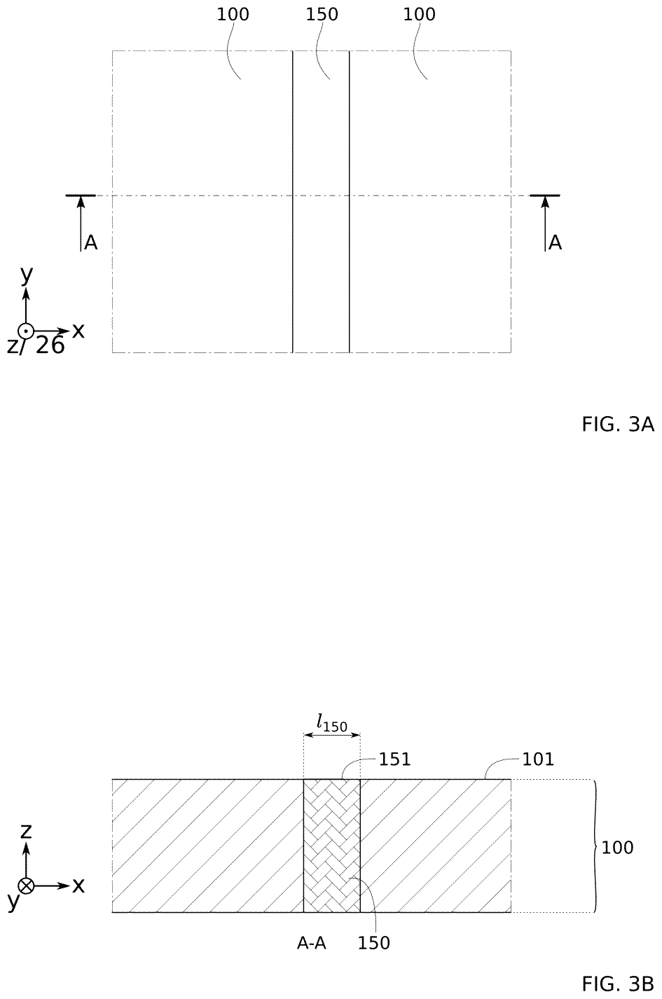

An embodiment of the method according to the invention will now be described in reference to FIGS. 3A to 23B. For reasons of clarity, these figures illustrate the obtaining of one single memory point. Naturally, these steps can make it possible to simultaneously obtain numerous memory points.

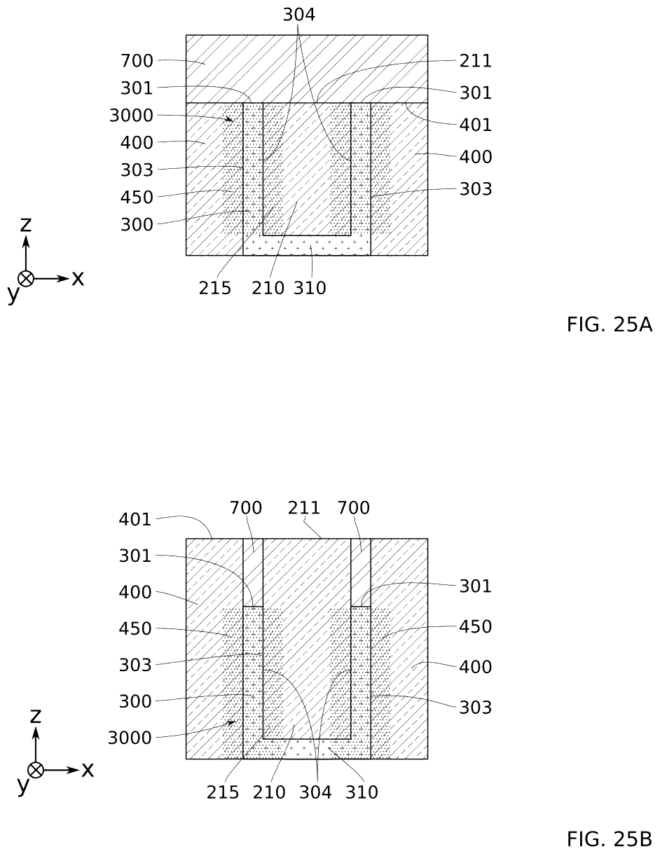

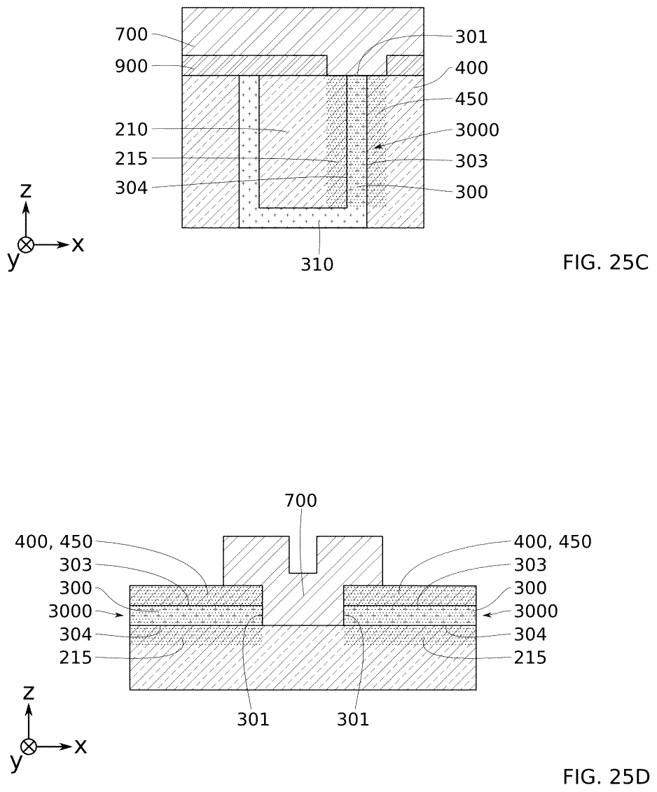

Moreover, these figures illustrate the manufacturing of a memory point, the structure of which can be qualified as a “WALL” structure. In this structure, the heating element, the memory layer and the upper electrode are stacked, in this order, along the stacking direction Z. The heating element moreover has, in the case of this structure, an invariable shape along a direction perpendicular (in this case, Y) to the stacking direction Z (for example, the shape of a cuboid or, seen as a cross-section, the shape of an “L”). The steps described below can however fully be adapted to the formation of memory points having other structures. Different examples of structures will be presented further, in reference to FIGS. 25A to 25D.

It must be noted that all the figures indexed “A” correspond to top views along the stacking direction Z, while all the figures indexed “B” correspond to side views.

FIGS. 3A and 3B illustrate the provision of a support layer 100. The support layer 100 has an upper face 101 extending mainly in a longitudinal plane XY.

The support layer 100 can correspond to a metal level of the back-end, typically the level M_{N-1}, or to a part of this level. It can be called lower metal line or also lower interconnecting line. It typically comprises at least one metal via 150, the upper face 151 of which is preferably flush with the upper face 101 of the support layer 100. The metal via 150 can, for example, be tungsten-based. It has a width 1150 along the first direction X, with preferably I₁₅₀≥1 nm, and preferably I₁₅₀≤500 nm.

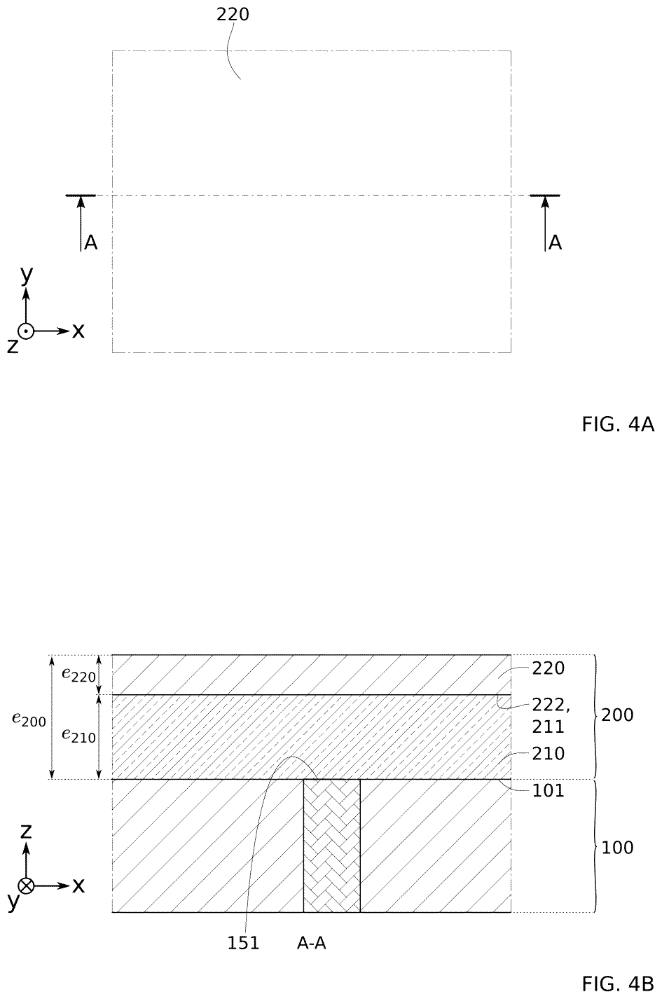

FIGS. 4A and 4B illustrate the formation of a dielectric layer 200 on the upper face 101 of the support layer 100. The dielectric layer 200 typically comprises a first dielectric layer 210 and a second dielectric layer 220, the first dielectric layer 210 extending from the upper face 101 of the support layer 100 and the second dielectric layer 220 extending over the first dielectric layer 210. Preferably, the first dielectric layer 210 and the second dielectric layer 220 are in contact with one another. In this scenario, the upper face 211 of the first dielectric layer 210 is in contact with the lower face 222 of the second dielectric layer 220.

The dielectric layer 200, the first dielectric layer 210 and the second dielectric layer 220 respectively have a thickness e₂₀₀, e₂₁₀ and e₂₂₀ along the stacking direction Z. As will emerge further, the thickness e₂₁₀ of the first dielectric layer 210 can determine the height h_{ec} of the heating element of the device 1 obtained at the end of the method. Thus, it is provided that e₂₁₀ is substantially equal to the height h_{ec} desired for the heating element.

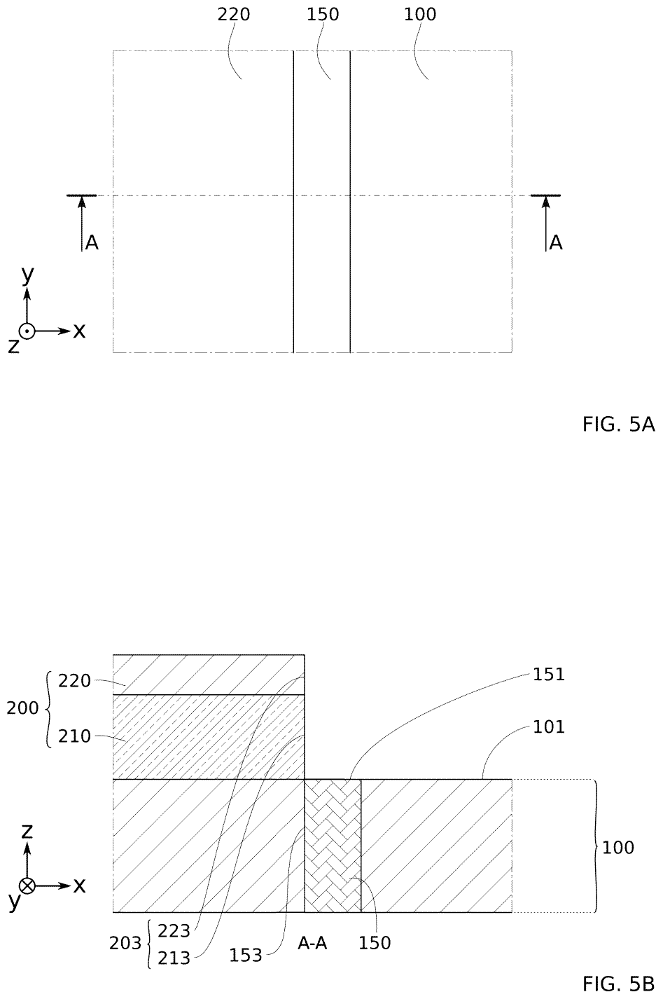

The dielectric layer 200 can, for example, be deposited over the entire support layer 100 (FIGS. 4A, 4B), then be partially etched in order to update at least partially, and preferably fully, the upper face 151 of the metal via 150 (FIGS. 5A, 5B).

Preferably, the etching of the dielectric layer 200 is configured to give it a flank 203 extending substantially perpendicularly, plus or minus 30%, to the upper face 101 of the support layer 100. The first dielectric layer 210 and the second dielectric layer 220 can be etched during one same etching step, or during two successive etching steps. In both cases, preferably, the flanks 213, 223 thus formed in these two layers 210, 220 are located in the extension of one another along the stacking direction Z. They together form the flank 203 of the dielectric layer 200.

The flank 203 of the dielectric layer 200 is ideally located in the extension of a flank 153, perpendicular to its upper face 151, of the metal via 150. The dielectric layer 200 can also be located in the part above the metal via 150, in which case its flank 203 protrudes with respect to the flank 153 of the metal via 150. This protrusion preferably does not exceed 50 nm. The flank 203 of the dielectric layer 200 can also be located, projecting into the longitudinal plane XY, removed with respect to the metal via 150. This can, in particular, be interesting, when it is sought that the metal via 150 connects a second heating element (the two heating elements can thus be selected separately using metal lines located above the corresponding memory points). The fact that the flank 203 is removed with respect to the metal via 150 thus makes it possible to leave more space above the metal via 150 for the presence of this second heating element.

It is understood that to produce a plurality of memory points 1000, the dielectric layer 200 will be structured so as to form a plurality of flanks 203 against each of which, as will be described below, a heating element 3000 will be formed. Preferably, each of the flanks 203 will be located above a distinct metal via 150.

At this stage of the method, it is possible to perform an implantation of a third doping species in the dielectric layer 200 (implantation not represented in the figures). In particular, a so-called doped portion 215 of the first dielectric layer 210 can be implanted, extending from the flank 203 of the latter.

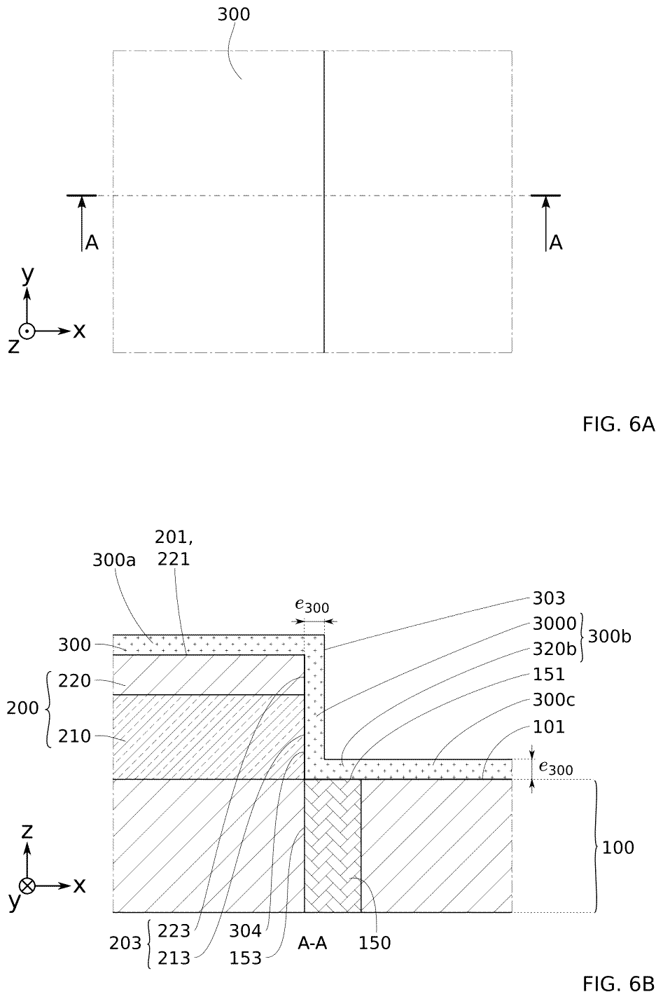

FIGS. 6A and 6B then illustrate the formation of a metal layer 300 on the dielectric layer 200 and on the support layer 100. The metal layer 300 can be deposited, preferably consistently:
a. on the upper face 201 of the dielectric layer 200, and more specifically on the upper face 221 of the second dielectric layer 220,
b. against the flank 203 of the dielectric layer 200, and therefore both against the flank 213 of the first dielectric layer 210 and against the flank 223 of the second dielectric layer 220,
c. on the upper face 101 of the support layer 100, and in particular, on the upper face 151 of the metal via 150.

Thus, the metal layer 300 moulds the shape of the dielectric layer 200. Moreover, it is preferably located in contact with the upper face 151 of the metal via 150.

Thus, three portions of the metal layer 300 are distinguished:
a. a first portion 300a extending above the plane into which the upper face 201 of the dielectric layer 200 extends,
b. a second portion 300b extending above the metal via 150 and optionally, if the dielectric layer 200 is removed with respect to the metal via 150, above a part of the support layer 100 not being the metal via 150 and not being covered by the dielectric layer 200,
c. a third portion 300c extending above the remaining part of the support layer 100 not being the metal via and not being covered by the dielectric layer 200.

The heating element 3000 of the memory point will be mainly formed by the second portion 300b and a part of the portion 300c.

The first portion 300a and the third portion 300c each have main extension planes parallel to the longitudinal plane XY and their thickness is thus measured along the stacking direction Z. The second portion 300b has an “L”-shape, composed of a portion called main portion extending from the flank 203 of the dielectric layer 200 and of a so-called “protrusion” portion 320b extending from the upper face 151 of the metal via 150. The protrusion 320b of the second portion 300b is separated from the dielectric layer 200 by the main portion of the L. The main portion of the “L” corresponds to a wall 3000 formed by the metal layer 300 against the flank 203 of the dielectric layer 200. This wall 3000 extends in particular between a first main flank 303 and a second main flank 304 of the metal layer 300. The wall 3000 is in contact with the upper face 151 of the metal via 150. It is, in particular, this wall 3000 which will have the function of a heating element within the memory point 1000.

The thickness of the wall 3000 is measured along the first direction X. The thickness of the protrusion 320b of the second portion 300b is measured along the stacking direction Z.

The metal layer 300 has a thickness e₃₀₀ measured along the first direction X or the stacking direction Z according to the portion considered. In the typical case of a consistent deposition, e₃₀₀ is identical in the three portions 300a, 300b, 300c of the metal layer 300. e₃₀₀ is preferably less than 10 nm.

In order to obtain a very good conformity of the metal layer 300, this step can be carried out by a chemical deposition such as a chemical vapour deposition (CVD), or an atomic layer deposition (ALD). It can, however, be considered to resort to other deposition methods. Deposition techniques making it possible to guarantee a good conformity of the thickness of the wall 3000 will be preferred.

It must be noted that the metal layer 3000 cannot be deposited on all the regions mentioned above, as long as it forms the wall 3000, as a minimum. It can be considered that the metal layer 300 is deposited only against the flank 203 of the dielectric layer 200, and therefore, from this deposition step, only form the wall 3000, or only against the flank 203 and on the upper face 151 of the metal via 150 and therefore, from this deposition step, only form the second portion 300b.

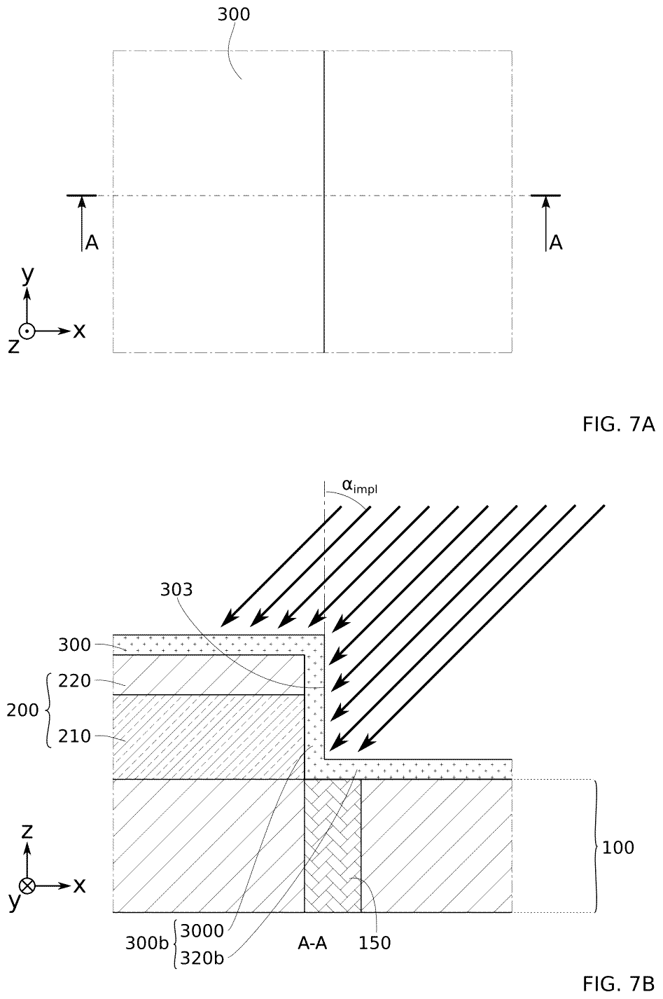

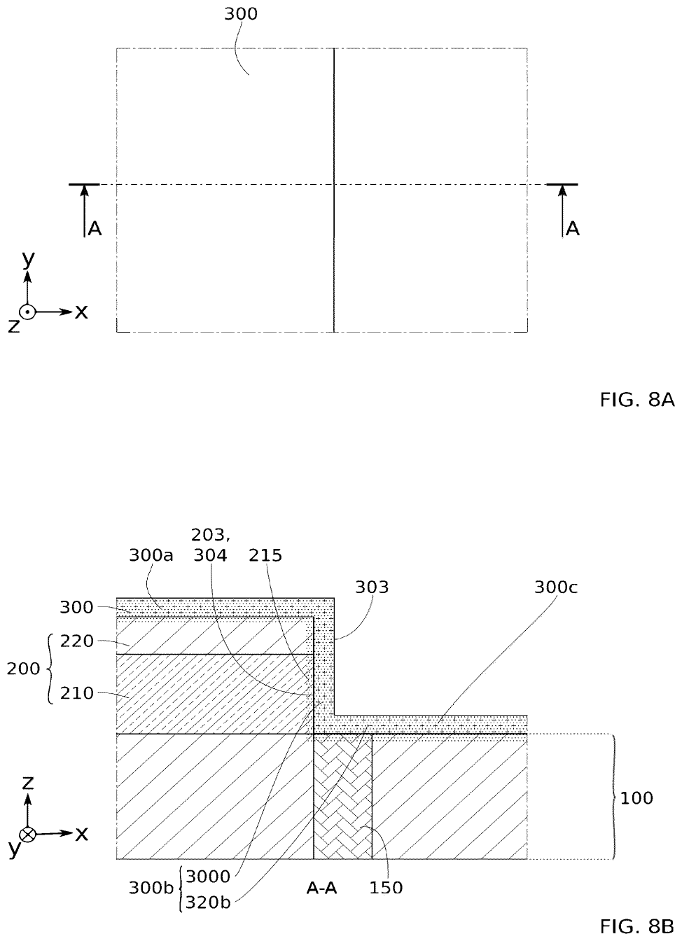

As illustrated in FIGS. 7A and 7B, it is possible at this stage of the method to carry out a step of implanting a second doping species in the metal layer 300 from at least its first main flank 303. This implantation step will be described in more detail further. Advantageously, the implantation extends until into the first dielectric layer 210, and optionally until into the second dielectric layer 220. The first dielectric layer 210 thus has a doped portion 215 extending from its flank 203. FIGS. 8A and 8B illustrate the doping being able to be obtained in the metal layer after the implantation performed during the step illustrated in FIG. 7.

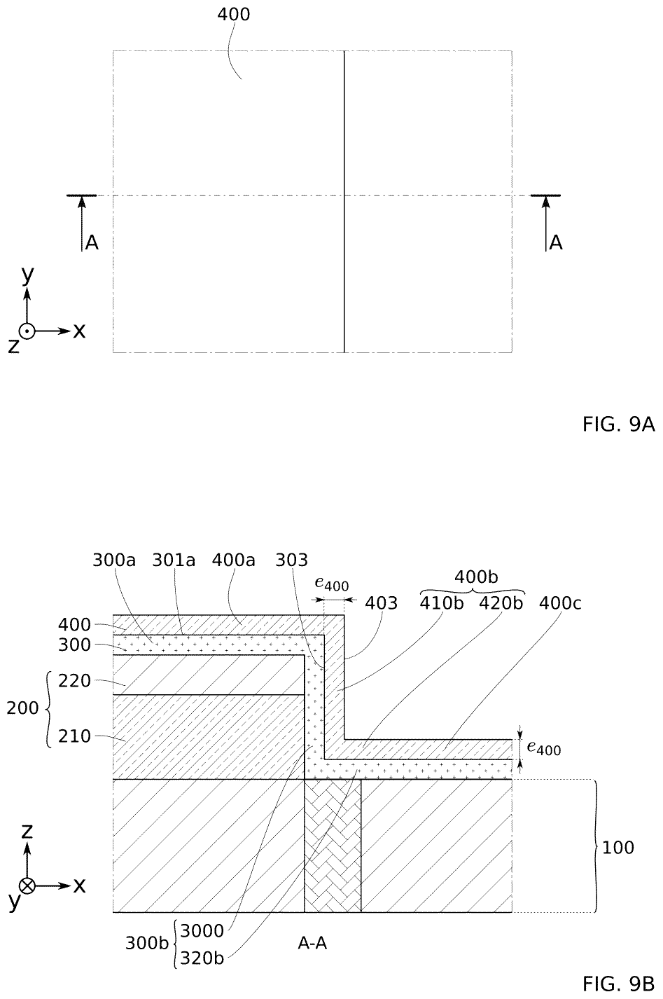

FIGS. 9A and 9B illustrate the formation of a first encapsulation layer 400 on the metal layer 300. This step is preferably carried out less than 24 hours after the formation of the metal layer 300. This makes it possible to avoid a too-high oxidation of the metal layer 300.

The first encapsulation layer 400 is, in particular, deposited, preferably consistently:
a. on an upper face 301a of the first portion 300a of the metal layer 300,
b. against the first main flank 303 of the metal layer 300,
c. on an upper face 301c of the third portion 300c of the metal layer 300.

Thus, the first encapsulation layer 400 moulds the shape of the metal layer 300. It is preferably located in direct contact with it.

Thus, three portions are distinguished from the first encapsulation layer 400:
a. a first portion 400a extending above the plane into which the upper face 301a of the first portion 300a of the metal layer 300 extends,
b. a second portion 400b extending above, along the stacking direction Z, the protrusion 320b of the second portion 300b of the metal layer 300, and, along the first direction X, to the side of the first main flank 303 of the metal layer 300,
c. a third portion 400c extending above the third portion 300c of the metal layer 300.

The first encapsulation layer 400 has a thickness e₄₀₀ measured along the first direction X or the stacking direction Z according to the portion considered. In the typical case of a consistent deposition, e₄₀₀ is identical in the three portions 400a, 400b, 400c of the first encapsulation layer 400. e₄₀₀ is typically greater than 5 nm, and preferably less than 30 nm.

Again, a deposition technique guaranteeing a good conformity of the first encapsulation layer 400 (CVD, ALD) will be preferred.

The second portion 400b of the first encapsulation layer 400 has a step-shape. This step comprises, in particular, an “L”-shaped part constituted:
a. of a main portion 410b extending between a first main flank 403 and a second main flank 404 of the first encapsulation layer 400, the second main flank 404 of the first encapsulation layer 400 being located facing the first main flank 303 of the metal layer 300,
b. of a protrusion 420b being located above, along the stacking direction Z, of the protrusion 320b defined by the second portion 300b of the metal layer 300, this protrusion 420b being separated from the wall 3000 by the main portion 410b of the “L”.

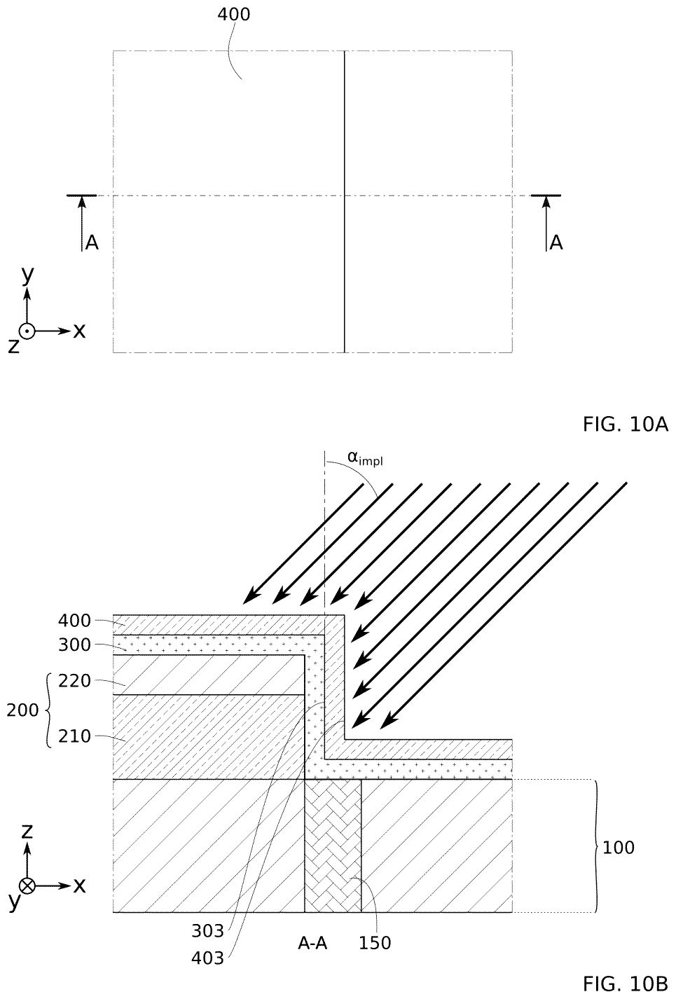

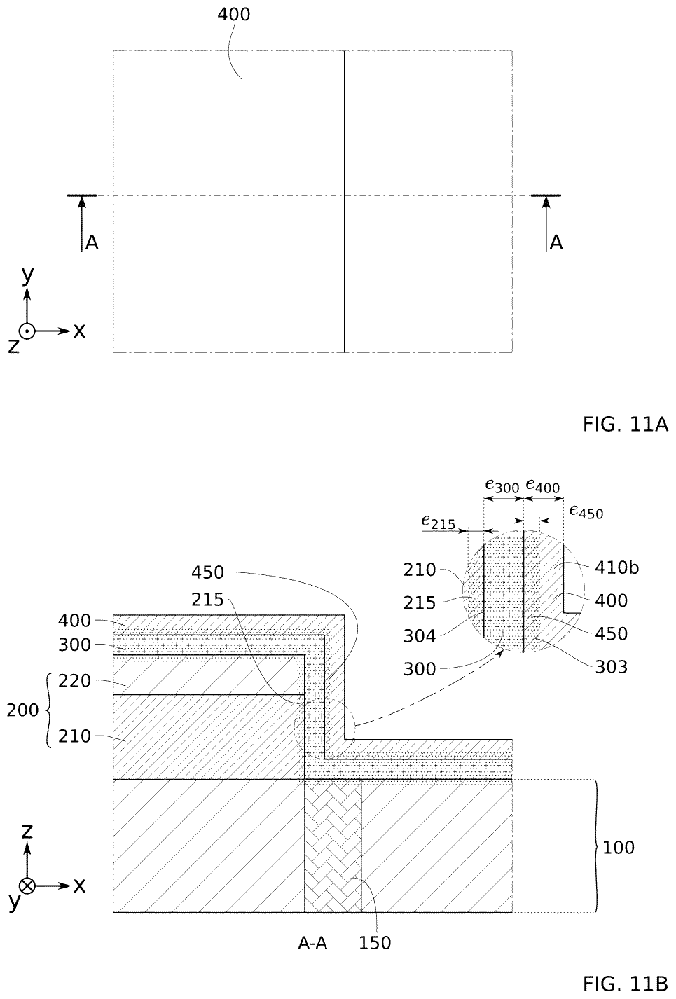

As illustrated in FIGS. 10A and 10B, it is possible, at this stage of the method, to carry out a step of implanting a first doping species in at least one portion of the main portion 410b of the “L” of the first encapsulation layer 400. This implantation is performed at this stage of the method from at least the first main flank 403 of the first encapsulation layer 400. Preferably, the implantation of the first species extends until into the metal layer 300. Advantageously, it also extends until into the dielectric layer 200, and in particular, into a doped portion 215 of the first dielectric layer 210. This implantation step will be described in more detail further. FIGS. 11A and 11B illustrate the doping being able to be obtained in the metal layer after the implantation performed during the step illustrated in FIG. 10.

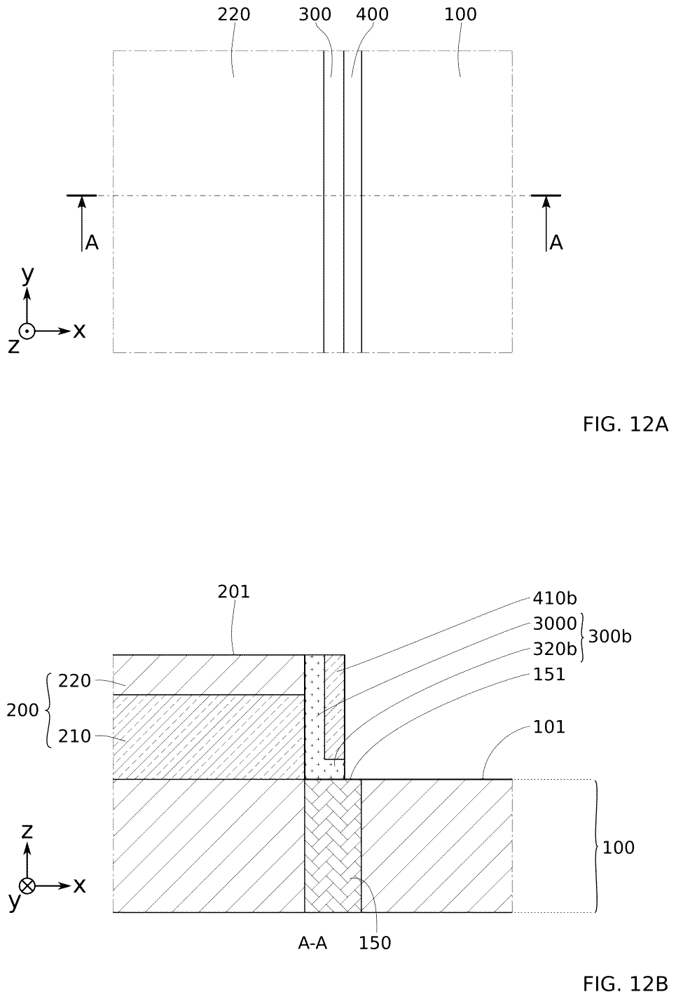

FIGS. 12A and 12B then illustrate a step of partially removing, typically by etching, the first encapsulation layer 400 and the metal layer 300. Advantageously, during this step, the following are removed:
a. the first portion 400a of the first encapsulation layer 400 and the first portion 300a of the metal layer 300,
b. the protrusion 420b of the second portion 400b of the first encapsulation layer 400, as well as the portion of the protrusion 320b of the underlying second portion 320b along the stacking direction Z. This removal makes it possible to make a part of the upper face 151 of the metal via 150 visible.
c. the third portion 400c of the first encapsulation layer 400 and the third portion 300c of the metal layer 300.

This removal can be performed using a reactive-ion etching (RIE) method. Anisotropic etching conditions will be favoured, in order to preferably etch the portions of layers, the main extension plane of which is parallel to the longitudinal plane XY while preserving the main portion 410b of the first encapsulation layer 400.

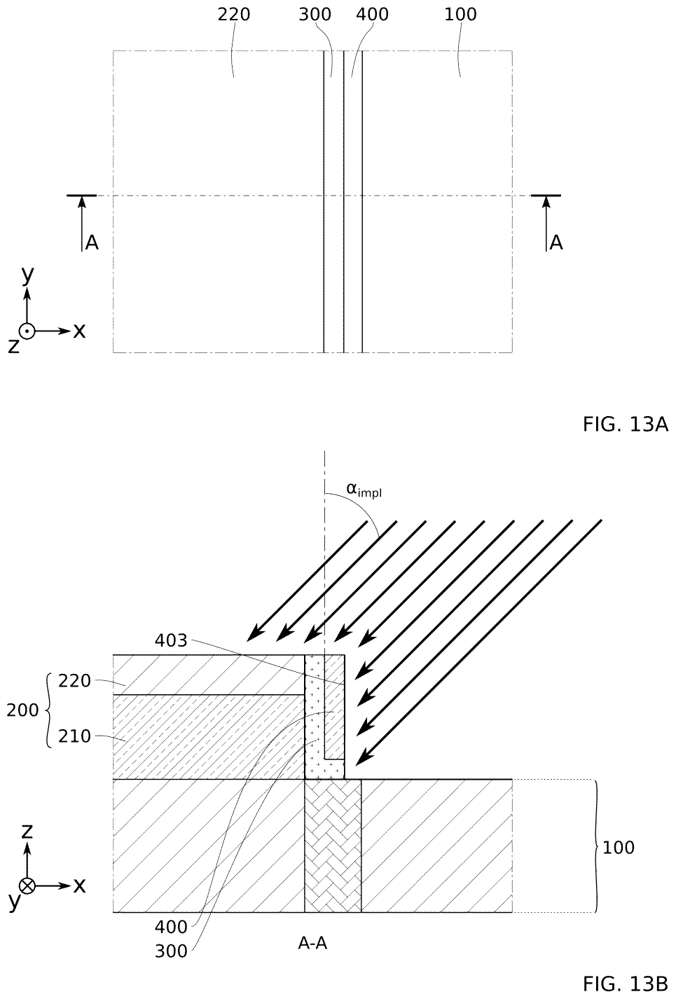

As illustrated in FIGS. 13A and 13B, it is possible, at this stage of the method, to carry out a step of implanting a doping species in the first encapsulation layer 400, preferably also in the metal layer 300 and preferably also in the dielectric layer 200. This implantation step will be described further. FIGS. 14A and 14B illustrate the doping being able to be obtained in the metal layer after the implantation performed during the step illustrated in FIG. 13. The doping species implanted during this step can be the first doping species, the second doping species, the third doping species or a distinct doping species.

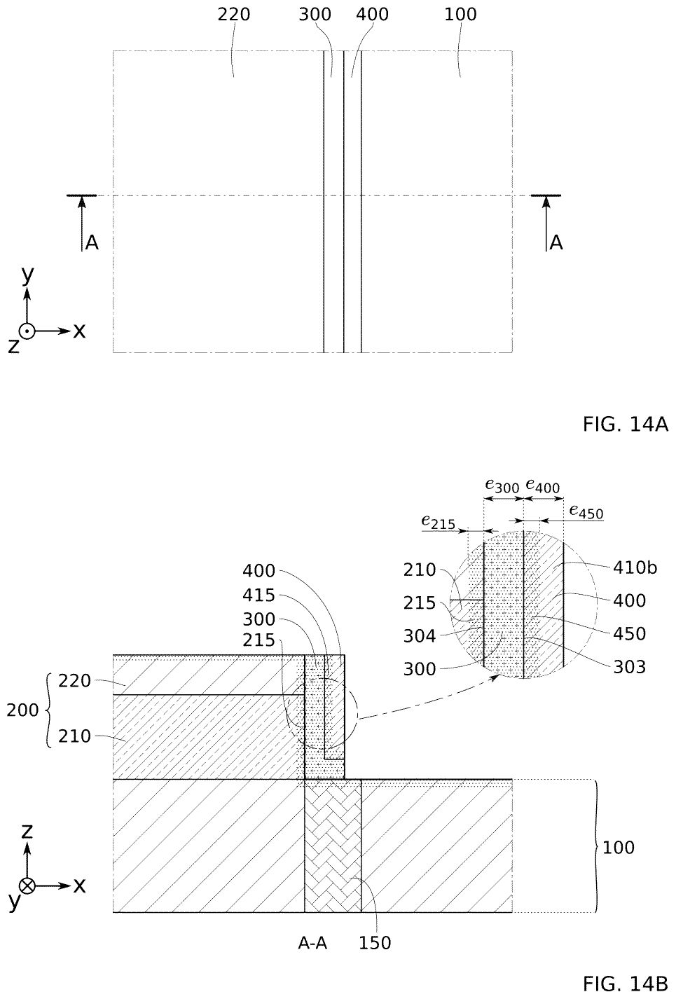

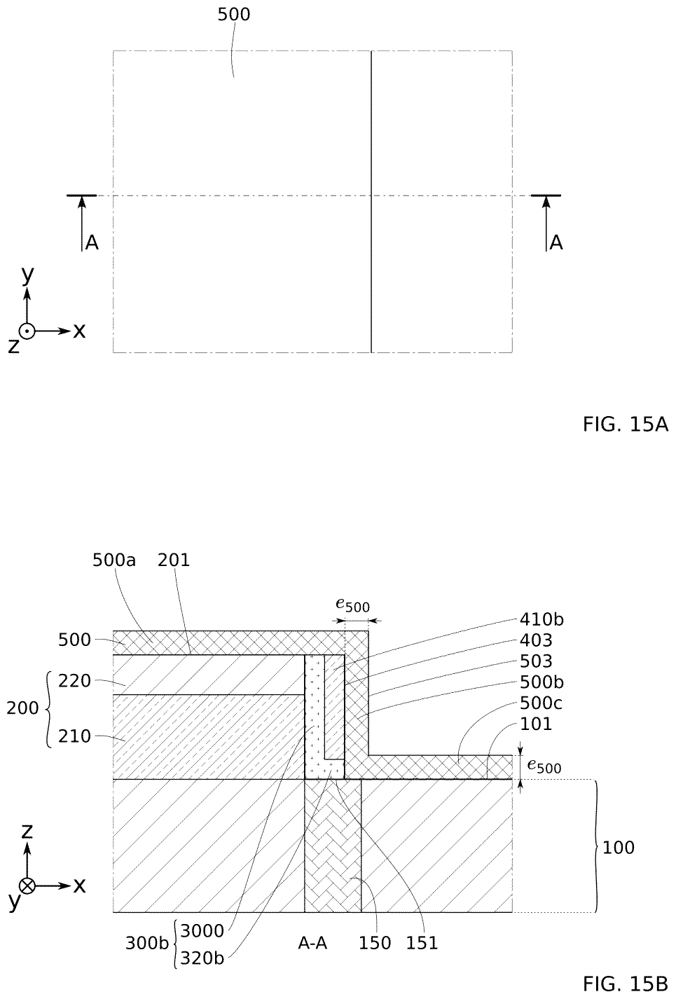

FIGS. 15A and 15B illustrate the optional formation of a second encapsulation layer 500 on the metal layer 300. The second encapsulation layer 500 is in particular deposited, preferably consistently:
a. on the upper face 201 of the support layer 200,
b. against the first main flank 403 of the first encapsulation layer 400,
c. on the visible portion of the upper face 151 of the metal via 150 and on the upper face 101 of the support layer 100.

Thus, three portions are distinguished from the second encapsulation layer 500:
a. a first portion 500a extending above, along the stacking direction Z, of the plane into which the upper face 201 of the dielectric layer 200 mainly extends,
b. a second portion 500b extending, in particular, along the first direction X, to the side of the main portion 410b of the first encapsulation layer 400 and to the side of the protrusion 320b of the metal layer 300. The second portion 500b is preferably in direct contact with the main portion 410b of the first encapsulation layer 400 and with the protrusion 320b of the metal layer 300. This second portion 500b also extends preferably from the portion of the upper face 151 of the metal via 150 made visible during the removal step illustrated in FIG. 12. It can also be in contact with a portion of the support layer 100 not being the metal via 150, as illustrated in FIG. 15B.
c. a third portion 500c extending above a portion of the support layer 100 not being covered by the support layer 200 and preferably not being the metal via.

The second encapsulation layer 500 has a thickness e₅₀₀ measured along the first direction X or the stacking direction Z according to the portion considered. In the typical case of a consistent deposition, e500 is identical in the three portions 500a, 500b, 500c of the second encapsulation layer 500. e₅₀₀ is typically greater than 5 nm, and preferably less than 30 nm.

Again, a deposition technique guaranteeing a good conformity of the first encapsulation layer 400 (CVD, ALD) will be preferred.

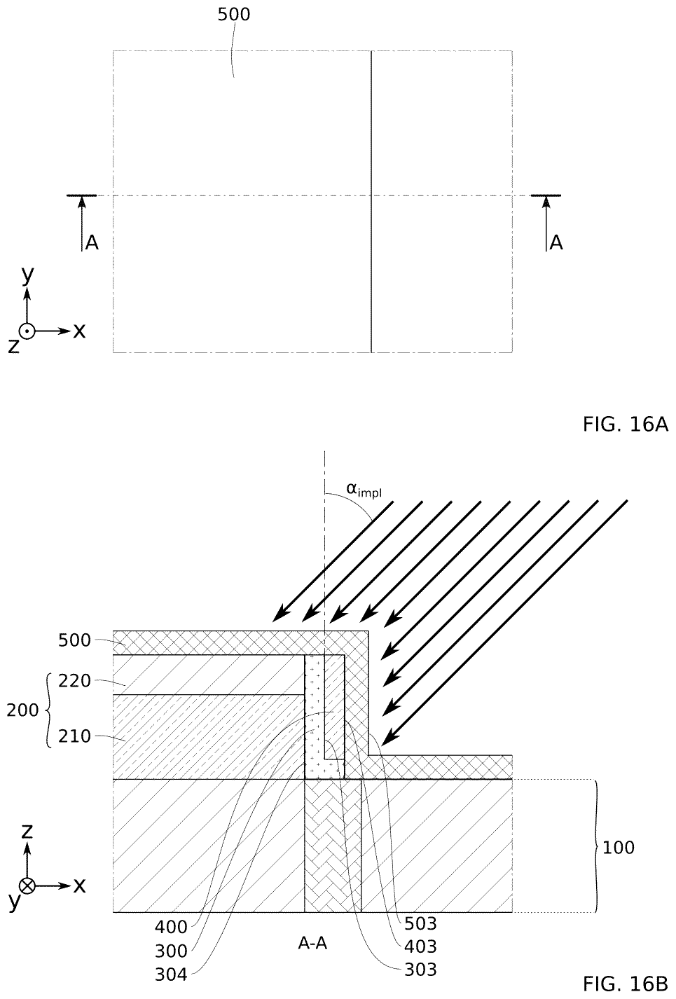

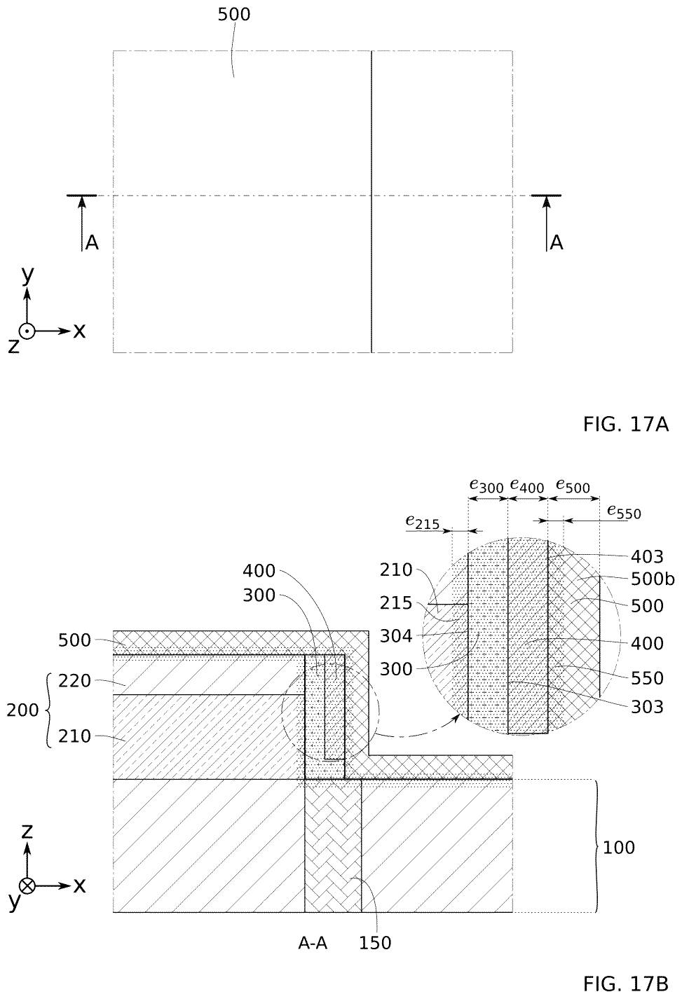

As illustrated in FIGS. 16A and 16B, it is possible, at this stage of the method, to carry out a step of implanting a doping species in the second encapsulation layer 500. The implantation preferably also extends into the first encapsulation layer 400, preferably also into the metal layer 300 and preferably also into the dielectric layer 200. This implantation step will be described in more detail further. FIGS. 17A and 17B illustrate the doping being able to be obtained in the metal layer after the implantation performed during the step illustrated in FIG. 16. The doping species implanted during this step can be the first doping species, the second doping species, the third doping species or a distinct doping species.

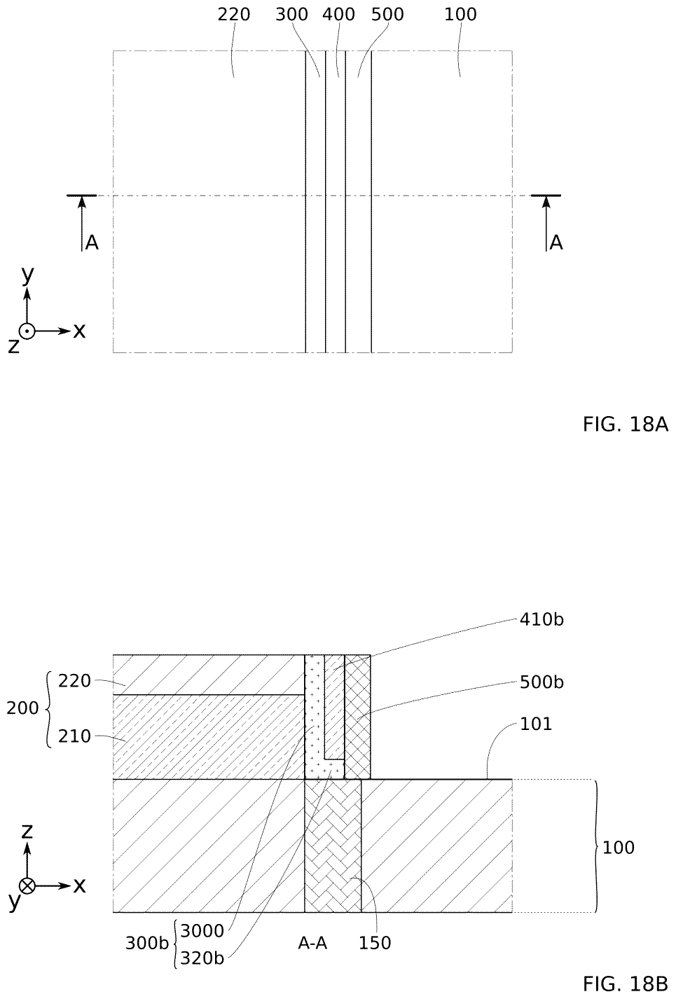

FIGS. 18A and 18B illustrate the partial removal of the second encapsulation layer 500.

Advantageously, during this step, the first portion 500a and the third portion 500c of the second encapsulation layer 500 are removed. This removal step is optional. In particular, the first portion 500a can be removed later in the method, as will be described further. The third portion 500c can be preserved in the stack, without consequence.

As illustrated in FIGS. 19A and 19B, it is possible at this stage of the method, to carry out a step of implanting a doping species in the second encapsulation layer 500. The implantation preferably also extends into the first encapsulation layer 400, preferably also into the metal layer 300, and preferably also into the dielectric layer 200. This implantation step will be described in more detail further. FIGS. 19A and 19B illustrate the doping being able to be obtained in the metal layer after the implantation performed during the step illustrated in FIG. 18.

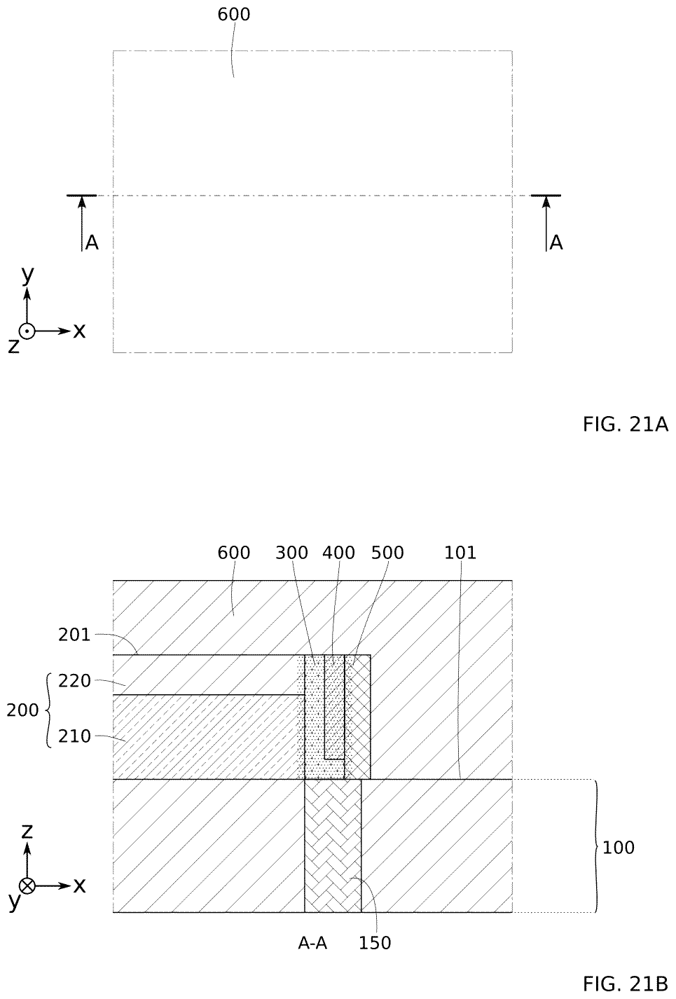

FIGS. 21A and 21B illustrate an optional step of forming a filling layer 600 above, along the stacking direction Z, of the support layer 200, of the metal layer 300, of the first encapsulation layer 400, of the second encapsulation layer 500 and of the portion of the support layer 100 not being covered by any of these layers 200, 300, 400, 500. The filling layer 600 can, for example, be SiO₂-based.

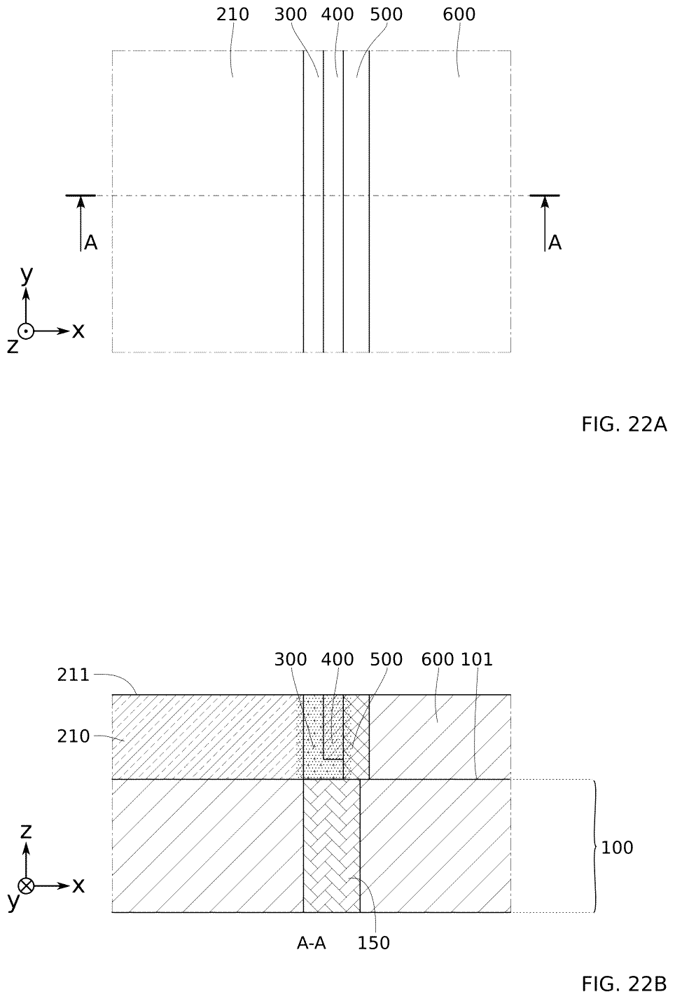

The filling layer 600 has an upper face 601 extending mainly into a plane parallel to the longitudinal plane XY. The deposition of this filling layer 600 thus makes it possible to create a continuous and substantially flat face from which a polishing step is carried out, represented by the passage from FIGS. 21A and 21B to FIGS. 22A and 22B.

This polishing step is preferably carried out by chemical mechanical polishing (CMP). The polishing is preferably configured to stop selectively on the upper face 211 of the first dielectric layer 210, after having fully removed the second dielectric layer 220, a portion of the wall 3000, a portion of the main portion 410b of the first encapsulation layer 400 and a portion of the main portion 510b of the second encapsulation layer 500, all these portions extending above, along the stacking direction Z, of the plane into which the upper face 211 of the first dielectric layer 210 mainly extends. If it has not been removed before, the first portion 500a of the second encapsulation layer 500 can be removed by this polishing step.

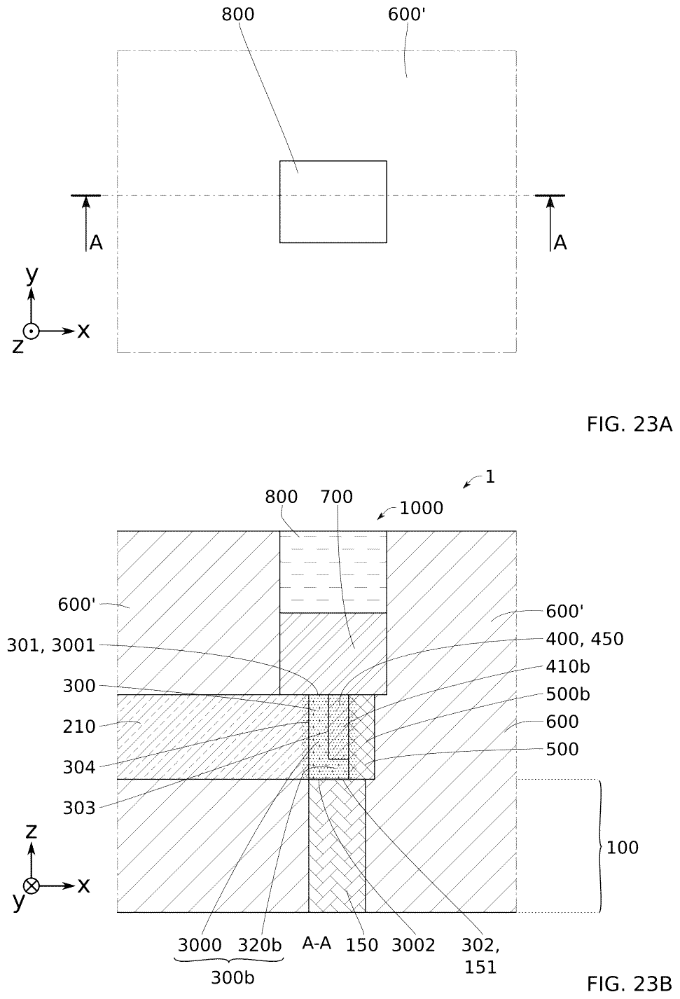

FIGS. 23A and 23B illustrate the formation on the wall 3000—and, advantageously, also on the encapsulation layers 400, 500—of a memory layer 700 and of an upper electrode 800. A secondary filling layer 600′ can also be formed around these elements, on the filling layer 600 and on the first support layer 210. The secondary filling layer 600′ can, for example, be SiO₂-based.

The assembly comprising the metal layer 300, the memory layer 700 and the upper electrode 800 forms a memory point 1000.

The structural features of this memory point 1000 will be described in more detail further.

### Implantation Step

The method according to the invention provides at least one implantation step aiming to implant, with a doping species, as a minimum, the first encapsulation layer 400, and preferably also the portion of the metal layer 300, which will become the heating element of the memory device 1 manufactured by the method. The following paragraphs aim to describe this implantation step more specifically.

The doping species implanted during this step can be one from among the following species: argon, carbon, nitrogen, silicon, xenon, titanium, tantalum, tungsten, germanium, oxygen, cobalt and neon. Several of these species can be implanted.

The implantation is typically performed at an energy of between 1 and 500 keV, for example, 12 keV.

The implantation is preferably configured such that the first encapsulation layer 400 is doped on a portion 450 having a thickness e₄₅₀ with e₄₅₀≥0.05*e₄₀₀, and preferably e₄₅₀≥0.10*e₄₀₀.

The implantation is moreover preferably configured such that the heating element 3000 is implanted over its entire thickness e_{ec}, typically equal to e₃₀₀₀, described further.

In all the embodiments of the implantation considered below, the implantation is performed along an implantation angle αᵢₘₚₗ measured with respect to the plane into which the first main flank 303 of the metal layer 300 mainly extends. αᵢₘₚₗ is therefore typically measured with respect to the transverse plane YZ. αᵢₘₚₗ is, in particular, adjusted according to the spacing between the memory points 1000 formed simultaneously by the method according to the invention. Thus, the narrower the memory points 1000 are, the lower αᵢₘₚₗ must be. Typically, αᵢₘₚₗ is between 15° and 75°, preferably between 25° and 45°.

Before the implantation step, the metal layer 300 has an electrical resistivity greater than 10² μΩ·cm, even greater than 10³ μΩ·cm, and typically less than 10⁴ μΩ·cm. After the implantation step, when this also aims for the metal layer 300, the latter preferably has an electrical resistivity less than 10³ μΩ·cm.

The stack provided at the start of the method according to the invention corresponds to any one of the stacks illustrated in FIGS. 9, 12, 15 and 18.

It can be fully considered that the implantation step is constituted of several implantation substeps, each implantation substep corresponding to one of the implantation steps described below. For example, an implantation substep can be provided between the formation of the metal layer 300 and the formation of the first encapsulation layer 400, in order to implant the metal layer and optionally the first dielectric layer 210, then an implantation substep between the formation of the first encapsulation layer 400 and the formation of the second encapsulation layer 500, in order to implant the first encapsulation layer 400 and optionally the layers that it covers (metal layer 300, first dielectric layer 210).

It is also possible that several implantations are performed successively, for example, to implant several doping species at the same layer(s).

According to an embodiment, the implantation of the first encapsulation layer 400 is performed before (FIGS. 10B and 13B) the step of forming the second encapsulation layer 500. According to another embodiment, it is performed after (FIGS. 16B and 19B). It can occur at the same time as the implantation of other layers, and in particular, at the same time as the implantation of the metal layer 300, and optionally as the implantation of the second encapsulation layer 500 (see the embodiments described further).

As mentioned above, the metal layer 300 is preferably also implanted.

According to an embodiment illustrated in FIG. 7B, the implantation of the metal layer 300 occurs when its first main flank 303 is not covered. In other words, in this embodiment, the first main flank 303 of the metal layer 300 is left free. The step of implanting the metal layer 300 is therefore carried out before the step of forming the first encapsulation layer 400 (and, if it is carried out, before the step of forming the second encapsulation layer 500).

According to another embodiment, the step of implanting the metal layer 300 is carried out after the step of forming the first encapsulation layer 400 and, if it is carried out, before the step of forming the second encapsulation layer 500. In this case, the implantation of the heating element 3000 of the device 1 is therefore performed through the first encapsulation layer 400. According to an example of this embodiment, the implantation is performed before the partial removal of the metal layer 300 and of the first encapsulation layer 400 described above (FIGS. 10B, 11B). According to another example, the implantation is performed after this partial removal (FIGS. 13B, 14B).

In this embodiment, the first encapsulation layer 400, and in particular, its main portion 410b, is also implanted. It is provided that this implantation is effective in at least one portion called doped portion 450 of the main portion 410b of the first encapsulation layer 400, and that this doped portion 450 preferably has a concentration of doping species greater than or equal to 5.1020 atoms/cm³. This doped portion 450 extends from the first main flank 303 of the metal layer 300 (see FIGS. 11B and 14B).

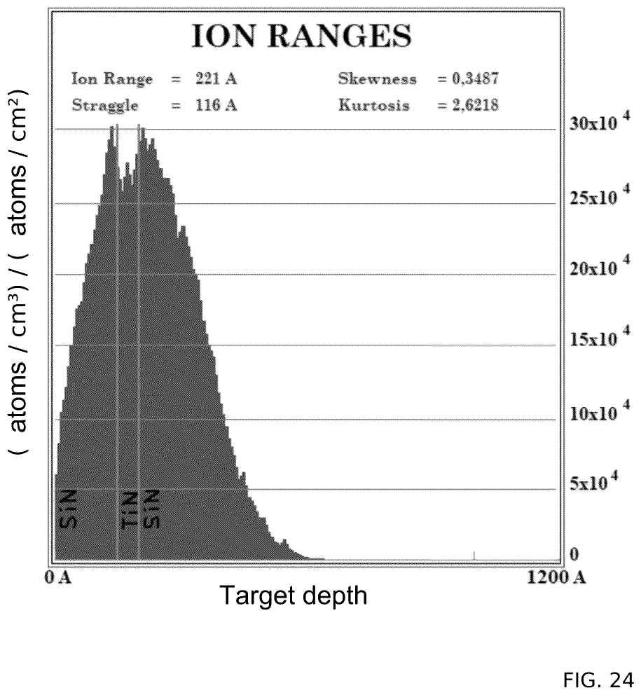

FIG. 24 represents the result of a software simulation of the carbon implantation of a SiN/TiN/SiN tri-layer. In this simulation, the first SiN layer can be assimilated to the first dielectric layer 210, the TIN layer to the heating element 3000 and the second SiN layer to the first encapsulation layer 400. The parameters have been adjusted, so as to simulate a 12 keV implantation of a dose of 10¹⁶ at·cm² centred in the heating element and also effective in the neighbouring portions of the dielectric layer and of the first encapsulation layer, at αᵢₘₚₗ=45°. It is observed that such an implantation causes a carbon peak in the heating element 3000 at a concentration of more than 25.10²⁰ atoms/cm³. The creation of a gradient in each of the SiN layers from the interface with the heating element is also observed. This gradient extends over around 20 nanometres.

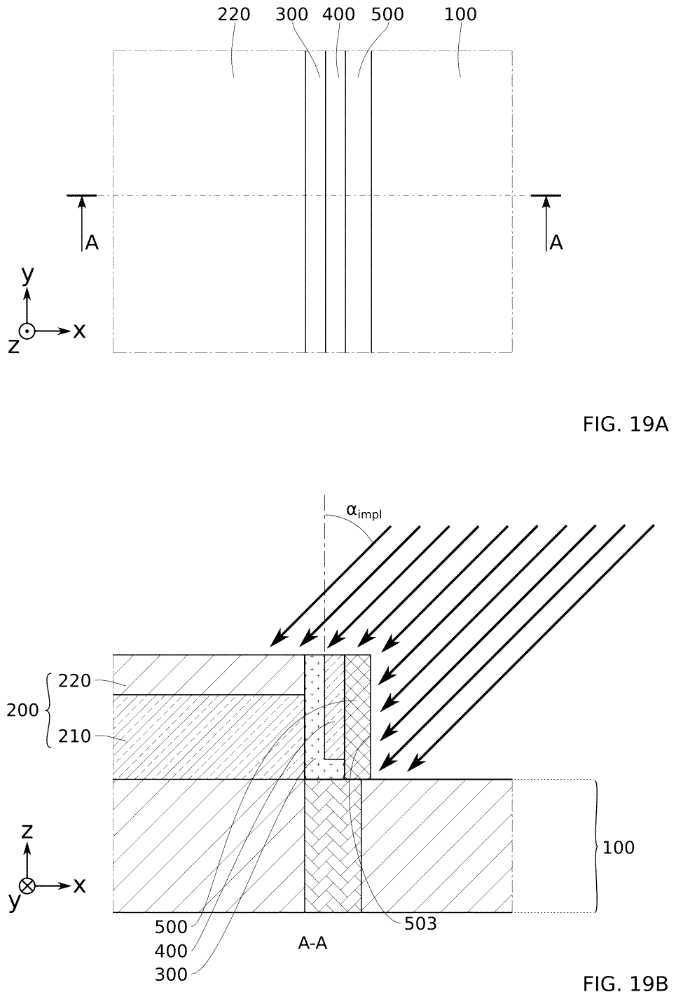

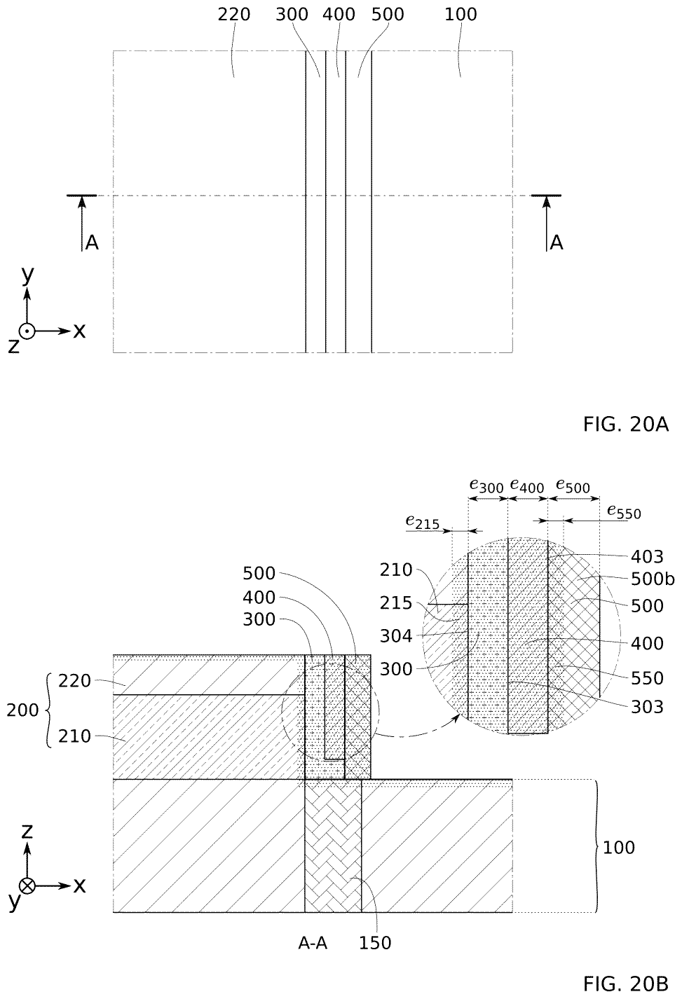

According to another embodiment, the step of implanting the metal layer 300 is carried out after the step of forming the first encapsulation layer 400 and after the step of forming the second encapsulation layer 500. In this case, the implantation of the heating element 3000 of the device 1 is therefore performed through the second encapsulation layer 500 and through the first encapsulation layer 400. According to an example of this embodiment, the implantation is performed before the partial removal of the second encapsulation layer 500 described above (FIGS. 16B, 17B). According to another example, the implantation is performed after this partial removal (FIGS. 19B, 20B) over a thickness e₄₅₀ taken perpendicularly to this same flank 303.

In this embodiment, the first encapsulation layer 400 is also implanted, preferably over its entire thickness e400. The second encapsulation layer 500, and in particular, its second portion 500b, is also implanted. It is provided that at least one portion called doped portion 550 of the second portion 500b of the second encapsulation layer 500 has a concentration of doping species greater than or equal to 1.1020 atoms/cm³. This doped portion 550 extends from the first main flank 403 of the first encapsulation layer 500 (see FIGS. 17B and 14B) over a thickness e₅₅₀ taken perpendicularly to this same flank 403.

For clarity, and in particular, to distinguish the different times of the method at which the implantation can be performed, the doping coming from the implantations illustrated in FIGS. 7, 10, 13, and 16 are only illustrated in FIGS. 8, 11, 14 and 17, respectively. The doping coming from the implantation illustrated in FIG. 19 is itself, illustrated up to FIG. 23.

It is understood that all the steps described above making it possible to lead to the memory point 1000 can be carried out, preferably simultaneously, above different zones of the support 100, in order to manufacture a plurality of memory points 1000.

As explained above, it has been proven that by carrying out an implantation step in the first encapsulation layer, its stoichiometry and its atomic structure are modified, which has the effect of reducing its heat transfer coefficient. This causes a thermal confinement effect of the heating element, and the heat coming from the latter is thus more dissipated towards the memory layer 700 than in the other surrounding regions. The implantation thus has the effect of improving the ratio between the energy provided to the heating element and the energy which is actually useful for the programming of the state of the memory layer 700.

As described in detail above, it has moreover been proven that by also implanting the metal layer 300, its stoichiometry and its atomic structure are modified and new chemical elements are added into this same layer. Unexpectedly, this has the effect of improving the temperature stability of the heating element 3000. This is particularly true when the implantation is performed through even the two encapsulation layer(s) 400, 500, as thus species are transferred from these layers to the heating element 3000.

Moreover, the implantation makes it possible to improve the resistivity of the heating element 3000. This induces a stronger Joule effect within the heating element 3000, and therefore a better control of the programming of the state of the memory layer 700. This increasing of the metal layer 300 is in particular due to the amorphisation of the latter during the implantation.

### Phase Change Memory Device

Another aim of the invention relates to the device 1 being able to be obtained by any one of the embodiments of the method described above.

### Wall Structure

A particular embodiment of the device 1 will now be described in reference to FIG. 23. This embodiment is based on a WALL-type memory point. It is understood, however, that other types of structures can be considered. These other structures will be described further.

FIG. 23 illustrates one single memory point 1000 of the device 1 according to the invention, but it is understood that the device 1 can comprise several of them.

The memory point 1000 comprises a metal layer 300 with the basis of a metal material. The metal layer 300 typically comprises a wall 3000 and a protrusion 320b. The wall 3000 extends between a first main flank 303 and a second main flank 304 of the metal layer 300. The wall 3000 and the protrusion 320b together form a bend, being able to also be called “L”. The protrusion 320b is however optional. The metal layer 300 can only comprise the wall 3000.

The first main flank 303 and the second main flank 304 of the metal layer 300 preferably extend parallel to the second direction Y and to the stacking direction Z.

The metal layer 300 has an upper face 301 and a lower face 302 opposite one another, and each extending substantially into a plane parallel to the longitudinal plane XY. The metal layer 300 extends fully between its upper face 301 and its lower face 302.

The wall 3000 has an upper face 3001 and a lower face 3002 opposite one another and each extending substantially into a plane parallel to the longitudinal plane XY. The upper face 301 of the metal layer 300 and the upper face 3001 of the wall 3000, on the one hand, and the lower face 302 of the metal layer 300 and the lower face 3002 of the wall 3000, on the other hand, are preferably combined. In other words, preferably, the wall 3000 extends over the entire height of the metal layer 300.

The memory point 1000 further comprises, on the upper face 301 of the metal layer 300, a memory layer 700 with the basis of a phase change material.

For example, the memory layer 700 can be with the basis or made of any material belonging to the ternary diagram of germanium Ge, antimony Sb and tellurium Te. For example, this material is chosen from among Ge₁Sb2Te₄, GeTe, Sb2Te₃, Ge7Sb1Te2. The memory layer 700 can also be with the basis or made of an alloy of a material of the ternary diagram of Ge, Sb and Te and of one or more element(s) from among the following: Si, As, Se, N, S, In, Ga, Bi.

The memory layer 700 has an upper face 701 and a lower face 702 opposite one another and each extending into a plane perpendicular to the stacking direction Z. The upper face 701 and the lower face 702 of the memory layer 700 are also called main faces 701, 702 of the memory layer.

The memory point 1000 further comprises, on the upper face 701 of the memory layer 700, a so-called upper electrode 800.

The wall 3000 constitutes the heating element 3000 of the memory point 1000.

The heating element 3000 is thermally coupled to the memory layer 700, such that at least some of the heat produced by the heating element 3000 by Joule effect is transferred, by conduction, to the memory layer 700. Preferably, the heating element 3000 is in contact with the memory layer 700.

The following paragraphs give specifications on the typical dimensions of the heating element and of the memory layer 700 in the case of a WALL structure such as represented in FIG. 23B.

The heating element 3000 has a thickness e_{ec}, taken perpendicularly to its main flanks 303, 304. This thickness is thus measured along the first direction X in the figures. Typically, eec is greater than 1 nm, preferably less than 50 nm, preferably less than 10 nm. For example, eec is substantially equal to 5 nm.

The heating element 3000 moreover has a height h_{ec} taken along the second main flank 304, along the stacking direction Z.

The heating element 3000 is configured such that h_{ec}>α*e_{ec}, with α>2, preferably α>5. Thus, the heating element 3000 has a height hec, along the direction Z, significantly relative to its thickness e_{ec} along the direction X.

The heating element 3000 further has a width l_{ec}, measured perpendicularly to h_{ec} and to e_{ec}.

According to an embodiment, l_{ec}>δ* e_{ec}, with δ>2, preferably δ>5. Thus, the heating element 3000 has a width l_{ec}, along the direction Y significantly relative to its thickness e_{ec} along the direction X.

With these relative dimensions hec, l_{ec}, and e_{ec}, the heating element 3000 has a wall shape which can be qualified as a wall.

The memory layer 700 has a thickness e_{cm}, measured perpendicularly to the main faces 701, 702 of the memory layer 700 and from one face to the other. Thus, e_{cm} is measured along the same direction as h_{ec}. Typically, e_{cm} is greater than 5 nm, preferably less than 200 nm, for example, equal to 50 nm.

The memory layer 700 further has a length Lem and a width l_{cm} measured perpendicularly to e_{cm} and perpendicularly to one another. L_{cm} is measured along the same direction as e_{ec} and l_{cm} is measured along the same direction as l_{ec}.

The device 1 is advantageously configured such that h_{ec}>βe_{cm}, with β>2, preferably β>5, preferably β>10.

The device 1 is advantageously configured such that L_{cm}>γ*e_{ec}, with γ>2, preferably γ>5, preferably γ>10. This makes it possible to concentrate the transmission of the heat emitted by Joule effect to a reduced zone of the memory layer 700. Indeed, such that the memory point 1000 is operational, it is sufficient that an electrical conduction is created between the main faces 701, 702 of the memory layer 700. This can be obtained by a change of state of the phase change material in a reduced portion of the memory layer 700 only. By concentrating the impact of the Joule effect on a reduced portion of the memory layer 700, the yield of the memory point 1000 is maximised.

The wall 3000 can extend over the entire width lom of the memory layer 700 (l_{ec}=l_{cm}), or be narrower than the memory layer 700 (l_{ec}<l_{cm}).

As mentioned above, the memory point 1000 can also have other types of structures. Different examples of structures which can be considered as presented below.

### So-Called “Ring” Structure

A second example of a structure is illustrated in FIG. 25A. In this example, the metal layer 300 differs from the example described in reference to FIG. 23B, in that it forms a closed contour projecting into the longitudinal plane XY. In particular, the first main flank 303 and the second main flank 304 of the metal layer 300 preferably each form a closed contour,, preferably circular, projecting into the longitudinal plane XY. The metal layer 300 can in particular surround the dielectric layer 210, which can have a cylindrical shape, preferably circular. The metal layer 300 preferably has a base 310, the main faces of which extend parallel to the longitudinal plane XY. The base 310 of the metal layer 300 is intended to be put into contact with a metal via. The metal layer 300 is preferably flush with the upper face 401 of the first encapsulation layer 400 and with the upper face 211 of the first dielectric layer 210.

In this example, the memory layer 700 is located above the metal layer 300, the first support layer 210 and the first encapsulation layer 400.

Due to the shape of the metal layer 300, this structure can be called “ring” structure.

In the case of a ring structure, the implantation can, for example, be performed after the formation of the first encapsulation layer 400, of the metal layer 300 and of a portion of the first stop layer 210 deposited against the second main flank 304. The implantation is thus preferably configured to be effective in a portion 450 of the first encapsulation layer 400, in the metal layer 300 and in the portion of the first stop layer 210 already deposited. The cavity defined by the metal layer 300 can then be ended by being filled by the first stop layer 210. The memory layer 700 can then be formed above the metal layer 300, the first encapsulation layer 400 and the first dielectric layer 210.

### So-Called “Confined Ring” Structure

A third example of a structure is illustrated in FIG. 25B. This structure is very close to the structure described above. It differs from it, however, in that the memory layer 700 forms a closed contour projecting into the longitudinal plane XY. It is located along the stacking direction Z in the extension of the metal layer 300. It separates in the longitudinal plane XY, the first encapsulation layer 400 of the first dielectric layer 210. This time, it is the memory layer 700 which is preferably flush with the upper face 401 of the first encapsulation layer 400 and with the upper face 211 of the first dielectric layer 210.

This structure therefore differs from the preceding one, in that the memory layer 700 is housed between the first encapsulation layer 400 and the first dielectric layer 210. For this reason, this structure can be called “confined ring” structure.

The implantation of a confined ring structure can be performed in the same way as in the case of a ring structure. A step of removing an upper portion of the metal layer 300 will however be provided in addition, in order to arrange an opening between the first encapsulation layer 400 and the first support layer 210, in which the memory layer 700 will then be formed.

### So-Called “Ring with Micro-Trench” Structure

A fourth example of a structure is illustrated in FIG. 25C. This example is differentiated from the second example, in that a dielectric layer 900 partially separates the metal layer 300 and the memory layer 700. The contact between these two layers is made on only one portion of the contour defined by the metal layer 300. The memory layer 700 extends above the dielectric layer 900, as well as in a through opening arranged in the dielectric layer 900, being able to be called trench. This trench opens onto the metal layer 300, and thus enables the contact between the memory layer 700 and the metal layer 300.

This structure can be called “ring with micro-trench” structure.

The implantation of a ring with micro-trench structure can be performed in the same way as in the case of a ring structure. A step of depositing the dielectric layer 900 will however be provided in addition, before the formation of the memory layer 700.

### So-Called “Bridge” Structure

A fifth example of a structure is illustrated in FIG. 25D. The main flanks 303, 304 of the metal layer 300 extend, in this example, in planes substantially parallel to the longitudinal plane XY. The metal layer 300 moreover preferably comprises two portions, separated from one another by the memory layer 700. Preferably, the memory layer 700 also extends above the first encapsulation layer 400. This structure can be called “bridge” structure.

It is possible, to form the device 1 according to this example of an embodiment of the invention, to provide a stack comprising the first dielectric layer 210, the metal layer 300 and the first encapsulation layer 400, to perform an implantation of the first encapsulation layer 400 (preferably, as well as of the metal layer 300 and of the first dielectric layer 210), then to form an opening in the first encapsulation layer 400 and in the metal layer 300, and finally to form the memory layer 700 at least partially in this opening.

Through the different embodiments described above, it clearly appears that the invention proposes an effective solution to improve the temperature stability of the heating element of a PCM-type memory device. The invention further makes it possible to improve the resistivity of this element, and, in the embodiments providing the presence of one or more encapsulation layers against the heating element, to improve its thermal confinement.

The invention is not limited to the embodiments described above, and extends to all the embodiments covered by the invention.

1. A phase change memory device comprising a memory point, the memory point comprising:
a metal layer with the basis of a metal material and forming a heating element,
a memory layer with the basis of a phase change material, the phase change material being configured such that the memory layer passes selectively from a first resistive state (LRS) having a first resistivity to a second resistive state (HRS) having a second resistivity greater than the first resistivity (LRS),
an upper electrode,
the heating element being intended to receive an electric current making it possible to produce heat by Joule effect and to transfer some of this heat to the memory layer so as to make the memory layer pass selectively from one from among the first resistive state (LRS) and the second resistive state (HRS), to the other from among the first resistive state (LRS) and the second resistive state (HRS),
the heating element has a first main flank and a second main flank, opposite one another, the memory device further comprising a first encapsulation layer extending from the first main flank of the metal layer,
wherein the first encapsulation layer has a so-called doped portion, having a doping with the basis of at least one species, called first doping species, the doped portion extending from the first main flank of the metal layer,
and wherein the metal layer has a doping with the basis of a second doping species, preferably identical to the first doping species.

2. The device according to claim 1, wherein the concentration of doping species in the doped portion is greater than or equal to 5.10²⁰ atoms/cm³.

3. The device according to claim 1, wherein the first encapsulation layer has a thickness e₄₀₀ taken along a direction perpendicular to the first main flank of the metal layer, the doped portion extending over a thickness e₄₅₀ along this same direction within the first encapsulation layer, with e₄₅₀>0.05*e₄₀₀.

4. The device according to claim 1, wherein the metal layer has a thickness e₃₀₀ between its first main flank and its second main flank, with e₃₀₀≤10 nm.

5. The device according to claim 1, wherein the first main flank of the metal layer is integrally doped.

6. The device according to claim 1, further comprising a first dielectric layer extending against the second main flank of the metal layer, the first dielectric layer having a so-called doped portion, having a doping with the basis of at least one species, called third doping species, identical to the first doping species, the doped portion of the first dielectric layer extending from the second main flank of the metal layer.

7. The device according to claim 1, wherein the first doping species is chosen from among the following species: silicon, carbon, argon, nitrogen, xenon, titanium, tantalum, tungsten, germanium, oxygen, cobalt, neon and their alloys.

8. The device according to claim 1, wherein the metal material is with the basis of at least one from among the following materials: TIN, TiC, TiSiN, TiSiCN, TiWN, TaN, TaCN.

9. A method for manufacturing a phase change memory device comprising a memory point, the method comprising the following steps:
providing an assembly comprising at least:
i. a metal layer with the basis of a metal material and intended to form a heating element for the memory point, the metal layer having a first main flank,
ii. a first encapsulation layer extending from the first main flank of the metal layer,
implanting a species called first doping species in a so-called doped portion of the first encapsulation layer, the doped portion extending from the main flank of the metal layer (300),
implanting a species called second doping species, identical to the first doping species, in the metal layer through the first encapsulation layer,
forming against a face of the metal layer, a stack comprising:
iii. a layer called memory layer with the basis of a phase change material, thermally coupled with the metal layer such that the heat produced by Joule effect by the metal layer is transferred to the memory layer,
iv. an upper electrode.

10. The method according to claim 9, wherein the first doping species is chosen from among the following species: silicon, carbon, argon, nitrogen, oxygen, xenon, titanium, tantalum, tungsten, germanium, cobalt, neon and their alloys.

11. The method according to claim 9, wherein the first encapsulation layer is with the basis of at least one from among the following materials: SiN, SiCN, SiC.

12. The method according to to claim 9, wherein the first encapsulation layer has a first main flank and a second main flank opposite one another, the second main flank facing the first main flank of the metal layer, the method further comprising the formation of a second encapsulation layer against the first main flank of the first encapsulation layer, and wherein the implantation of the second doping species in the metal layer is performed through the second encapsulation layer.

13. The method according to claim 9, wherein providing the assembly comprises the following steps:
providing a support layer having an upper face extending mainly into a plane parallel to the longitudinal plane (XY),
forming a dielectric layer on a portion of the upper face of the support layer, the dielectric layer having a flank extending into a plane parallel to the transverse plane (YZ),
forming at least against the flank of the support layer, and on the upper face of the support layer, the metal layer.

14. The method according to claim 13, wherein the dielectric layer comprises a first dielectric layer and a second dielectric layer, the second dielectric layer and the support layer being separated by the first dielectric layer, the method further comprising a step of polishing a portion of the metal layer and of the second dielectric layer, with a selective stop on the first dielectric layer.
